(19) United States
(12) Patent Application Publication
(10) Pub. No.: US 2012/0112777 A1
(43) Pub. Date: May 10, 2012

(54) ELECTRONIC DEVICE PUSHING APPARATUS, ELECTRONIC DEVICE TEST APPARATUS, AND INTERFACE DEVICE

(75) Inventors: Mitsunori Aizawa, Saitama (JP); Akihiko Ito, Saitama (JP); Noboru Masuda, Saitama (JP)

(73) Assignee: ADVANTEST CORPORATION, Tokyo (JP)

(21) Appl. No.: 13/383,537

(22) PCT Filed: Jul. 14, 2009
(86) PCT No.: PCT/JP2009/062734

§ 371 Date: Jan. 11, 2012

(51) Int. Cl. G01R 31/00

(52) U.S. Cl. 324/750.08; 324/750.25; 324/750.03

(57) ABSTRACT

An electronic device pushing apparatus includes a pushing unit which has: a plurality of pushers which contact DUTs; and base plate on which the plurality of pushers are provided. A rigidity of the base plate is set to a rigidity which is lower relative to the rigidity of a spacing frame of the HIFIX.

### TECHNICAL FIELD

The present invention relates to an electronic device pushing apparatus which pushes semiconductor integrated circuit devices or other devices under test to sockets on a HIFIX (interface device) which is mounted on a test head, an electronic device test apparatus comprising the same, and an interface device which is mounted on the test head.

### BACKGROUND ART

As an electronic device pushing apparatus which pushes devices under test (below, simply referred to as “DUTs”) to sockets, one is known which individually provides bellofram cylinders for the pushers which abut against the DUTs.

### SUMMARY OF INVENTION

### Technical Problem

When pushing DUTs to sockets, the HIFIX (High Fidelity Tester Access Fixture) flexes due to the pushing force, but in the above art, bellofram cylinders are used to impart the individual pushers to independent floating structures so as to thereby absorb the flexing.

On the other hand, as sockets are provided in increasingly higher densities at HIFIX's, the space for individually providing the respective pushers with bellofram cylinders can no longer be secured. Therefore, there is the problem that it is not possible to deal with the flexing which occurs at the HIFIX and sometimes sufficient contact cannot be secured between the DUTs and the sockets.

The problem to be solved by the present invention is the provision of an electronic device pushing apparatus, electronic device test apparatus, and interface device which can suppress poor contact between devices under test and sockets.

### Solution to Problem

(1) According to the present invention, there is provided an electronic device pushing apparatus which pushes devices under test to sockets on an interface device which is mounted on a test head, the electronic device pushing apparatus characterized in that the apparatus comprises a pushing unit which has: a plurality of pushers which contact the devices under test; and a base plate on which the plurality of pushers are provided, and the base plate has a rigidity which is lower relative to a rigidity of a holding member which holds the sockets in the interface device (see claim 1).

While not particularly limited in the invention, preferably the pushing unit has a temperature regulating plate which regulates a temperature of the devices under test, and the temperature regulating plate is stacked over the base plate (see claim 2).

While not particularly limited in the invention, preferably the temperature regulating plate has a channel through which at least one of a cooling medium or heating medium flows (see claim 3).

While not particularly limited in the invention, preferably the holding member is a spacing frame which holds socket boards on which the sockets are mounted in the interface device (see claim 4).

While not particularly limited in the invention, preferably a plate stack which comprises the base plate and the temperature regulating plate stacked together has a rigidity which is lower relative to the rigidity of the holding member (see claim 5).

While not particularly limited in the invention, preferably the apparatus comprises a moving means for moving the pushing unit toward the sockets, and the pushing unit has a cylinder which applies a predetermined pressure to the base plate (see claim 6).

While not particularly limited in the invention, preferably the pushing unit has: a cylinder which applies a predetermined pressure to the base plate; and a shaft which is arranged between the cylinder and the base plate and which passes through the temperature regulating plate (see claim 7).

While not particularly limited in the invention, preferably the apparatus comprises a moving means for moving the pushing unit toward the sockets (see claim 8).

While not particularly limited in the invention, preferably the pushing unit comprises a heat conduction member which is stacked between the base plate and the temperature regulating plate and which thermally connects the base plate and the temperature regulating plate, and the heat conduction member is able to deform together with the base plate (see claim 9).

While not particularly limited in the invention, preferably the heat conduction member is a bag member in which a fluid is filled (see claim 10).

While not particularly limited in the invention, preferably the heat conduction member is a sheet-shaped member which can elastically deform (see claim 11).

While not particularly limited in the invention, preferably the apparatus comprises a moving means for moving the pushing unit toward the sockets, and the pushing unit has: a cylinder which applies a predetermined pressure to the base plate; and a shaft which is arranged between the cylinder and the base plate and which passes through the temperature regulating plate and the heat conduction member (see claim 12).

(2) According to the present invention, there is provided an electronic device pushing apparatus which pushes devices under test to sockets on an interface device which is mounted on a test head, the electronic device pushing apparatus characterized in that the apparatus comprises a plurality of pushing units which push the devices under test, each of the pushing units has: a plurality of pushers which contact the devices under test; and a base plate on which the plurality of pushers are provided, and the plurality of pushing units can move independently of each other (see claim 13).

While not particularly limited in the invention, preferably, a holding member which holds the sockets in the interface device is a spacing frame which holds socket boards on which the sockets are mounted (see claim 14).

While not particularly limited in the invention, preferably the apparatus comprises a moving means for simultaneously moving the plurality of pushing units toward the sockets, and each of the pushing units has a cylinder which applies a certain pressure to the base plate (see claim 15).

While not particularly limited in the invention, preferably each of the pushing units has a temperature regulating plate which is stacked on the base plate and which regulates the temperature of the devices under test (see claim 16).

While not particularly limited in the invention, preferably the temperature regulating plate has a channel through which at least one of a cooling medium or heating medium flows (see claim 17).

While not particularly limited in the invention, preferably the apparatus comprises a channel connecting means for connecting channels of the temperature regulating plates, and the channel connecting means is interposed between the plurality of pushing units (see claim 18).

While not particularly limited in the invention, preferably each of the pushing units comprises a heat conduction member which is stacked between the base plate and the temperature regulating plates and which thermally connects the base plate and the temperature regulating plates (see claim 19).

While not particularly limited in the invention, preferably the heat conduction member is bag member in which a fluid is filled (see claim 20).

While not particularly limited in the invention, preferably the heat conduction member is a sheet-shaped member which can elastically deform (see claim 21).

(3) According to the present invention, there is provided an electronic device pushing apparatus which pushes devices under test to sockets on an interface device which is mounted on a test head, the electronic device pushing apparatus characterized in that the apparatus comprises: a pushing unit which pushes the devices under test; and a moving means for moving the pushing unit toward the sockets, and the pushing unit has: a plurality of base plates on which pluralities of pushers which contact the devices under test are respectively provided; a plurality of cylinders which apply predetermined pressure to the base plates; and a plurality of shafts which are arranged between the base plates and the cylinders (see claim 22).

While not particularly limited in the invention, preferably the pushing unit has a temperature regulating plate which regulates the temperature of the devices under test, and the shaft passes through the temperature regulating plate (see claim 23).

While not particularly limited in the invention, preferably the temperature regulating plate has a channel through which at least one of a cooling medium or heating medium flows (see claim 24).

While not particularly limited in the invention, preferably the pushing unit comprises a heat conduction member which is stacked between the base plate and the temperature regulating plate and which thermally connects the base plate and the temperature regulating plate, and the shaft passes through the heat conduction member (see claim 25).

While not particularly limited in the invention, preferably the heat conduction member is a bag member in which a fluid is filled (see claim 26).

While not particularly limited in the invention, preferably the heat conduction member is a sheet-shaped member which can elastically deform (see claim 27).

(4) According to the present invention, there is provided an electronic device pushing apparatus which pushes devices under test to sockets on an interface device which is mounted on a test head, the electronic device pushing apparatus characterized by comprising: a base plate on which a plurality of pushers which contact the devices under test are provided; and a coupling means which couples a holding member which holds the sockets in the interface device to the base plate (see claim 28).

While not particularly limited in the invention, preferably the apparatus comprises a temperature regulating plate which regulates the temperature of the devices under test, and the temperature regulating plate is stacked on the base plate (see claim 29).

While not particularly limited in the invention, preferably the temperature regulating plate has a channel through which at least one of a cooling medium or heating medium flows (see claim 30).

While not particularly limited in the invention, preferably the holding member is a spacing frame which holds socket boards on which the sockets are mounted in the test head (see claim 31).

While not particularly limited in the invention, preferably the apparatus comprises a moving means for moving the pushing unit toward the sockets, and the pushing unit has a cylinder which applies a predetermined pressure to the base plate (see claim 32).

(5) According to the present invention, there is provided an electronic device test apparatus which tests devices under test, the electronic device test apparatus characterized by comprising: a test head on which an interface device which has sockets which electrically contact the devices under test is mounted; and the above electronic device pushing apparatus which pushes the devices under test to the sockets (see claim 33).

(6) According to the present invention, there is provided an interface device which has sockets which electrically contact devices under test, which is mounted on a test head, and which electrically relays signals between the devices under test and the test head, the interface device characterized in that the device comprises a holding member which holds the sockets, and the holding member has a rigidity which is higher relative to a rigidity of a base plate on which a plurality of pushers which push the devices under test are provided (see claim 34).

While not particularly limited in the invention, preferably the holding member is a spacing frame which holds socket boards on which the sockets are mounted (see claim 35).

### Advantageous Effects of Invention

(1) In the present invention, by making the rigidity of the base plate of the pushing unit lower relative to the rigidity of the holding member of the interface device, the base plate deforms so as to match the flexing of the holding member, so the occurrence of poor contact between the devices under test and the sockets can be suppressed.

(2) Alternatively, in the present invention, a plurality of pushing units which respectively have pluralities of pushers can move independently from each other, so flexing of the interface device can be absorbed and the occurrence of poor contact between the devices under test and the sockets can be suppressed.

(3) Alternatively, in the present invention, a plurality of base plates are independently pushed through shafts, so flexing of the interface device can be absorbed and the occurrence of poor contact between the devices under test and the sockets can be suppressed.

(4) Alternatively, in the present invention, a coupling means is used to couple the base plate of the pushing unit and the holding member of the interface device, so flexing of the interface device can be suppressed and the occurrence of poor contact between the devices under test and the sockets can be suppressed.

### BRIEF DESCRIPTION OF DRAWINGS

FIG. 1 is a schematic plan view showing the overall configuration of an electronic device test apparatus in a first embodiment of the present invention.

FIG. 2 is a plan view showing a customer tray in the first embodiment of the present invention.

FIG. 3 is a side view of FIG. 2.

FIG. 4 is a cross-sectional view along the line IV-IV of FIG. 2.

FIG. 5 is a plan view showing contact plates in the first embodiment of the present invention.

FIG. 6 is a plan view showing a state of coupling the contact plates shown in FIG. 5.

FIG. 7 is a side view of FIG. 5.

FIG. 8 is a cross-sectional view along the line VIII-VIII of FIG. 5.

FIG. 9 is a side view of a first device transfer apparatus of the first embodiment in the present invention.

FIG. 10 is a plan view of FIG. 9.

FIG. 11 is a perspective view showing a holding mechanism of the first device transfer apparatus shown in FIG. 9.

FIG. 12 is a plan view of a reinforcing plate in the first embodiment of the present invention.

FIG. 13 is a side view of FIG. 12.

FIG. 14 is a plan view showing a state where the reinforcing plate shown in FIG. 12 carries the contact plates.

FIG. 15 is a side view of FIG. 14.

FIG. 16 is a side view showing the operation of the first device transfer apparatus of the first embodiment in the present invention (part 1).

FIG. 17 is a side view showing the operation of the first device transfer apparatus of the first embodiment in the present invention (part 2).

FIG. 18 is a side view showing the operation of the first device transfer apparatus of the first embodiment in the present invention (part 3).

FIG. 19 is a cross-sectional view showing the operation of placing contact plates over a customer tray in the first embodiment of the present invention.

FIG. 20 is a cross-sectional view showing the state where contact plates are placed over a customer tray in the first embodiment of the present invention.

FIG. 21 is a side view showing the operation of the first device transfer apparatus of the first embodiment in the present invention (part 4).

FIG. 22 is a cross-sectional view showing the operation of turning over contact plates and a customer tray in the first embodiment of the present invention.

FIG. 23 is a side view showing the operation of the first device transfer apparatus of the first embodiment in the present invention (part 5).

FIG. 24 is a cross-sectional view showing the operation of removing a customer tray from contact plates after being inverted in the first embodiment of the present invention.

FIG. 25 is a plan view showing a first interval changing apparatus in the first embodiment of the present invention.

FIG. 26 is a side view of FIG. 25.

FIG. 27 is a side view showing a movable head of a first interval changing apparatus in the first embodiment of the present invention.

FIG. 28 is a plan view of the movable head as seen from A of FIG. 27.

FIG. 29 is a plan view showing a conveyance operation of contact plates by the first interval changing apparatus in the first embodiment of the present invention (part 1).

FIG. 30 is a plan view showing a conveyance operation of contact plates by the first interval changing apparatus in the first embodiment of the present invention (part 2).

FIG. 31 is a plan view showing a setting operation of contact plates by the first interval changing apparatus in the first embodiment of the present invention.

FIG. 32 is a side view showing a plate moving apparatus and pushing apparatus in the first embodiment of the present invention.

FIG. 33 is a plan view showing the plate moving apparatus and pushing apparatus in the first embodiment of the present invention.

FIG. 34 is a cross-sectional view of a pushing apparatus in the first embodiment of the present invention.

FIG. 35 is a side view showing the operation of the plate moving apparatus and pushing apparatus in the first embodiment of the present invention (part 1).

FIG. 36 is a side view showing the operation of the plate moving apparatus and pushing apparatus in the first embodiment of the present invention (part 2).

FIG. 37 is a side view showing the operation of the plate moving apparatus and pushing apparatus in the first embodiment of the present invention (part 3).

FIG. 38 is a side view showing the operation of the plate moving apparatus and pushing apparatus in the first embodiment of the present invention (part 4).

FIG. 39 is a side view showing the operation of the plate moving apparatus and pushing apparatus in the first embodiment of the present invention (part 5).

FIG. 40 is a side view showing the operation of the plate moving apparatus and pushing apparatus in the first embodiment of the present invention (part 6).

FIG. 41 is a side view showing the operation of the plate moving apparatus and pushing apparatus in the first embodiment of the present invention (part 7).

FIG. 42 is a side view showing the operation of the plate moving apparatus and pushing apparatus in the first embodiment of the present invention (part 8).

FIG. 43 is a plan view showing a second interval changing apparatus in the first embodiment of the present invention.

FIG. 44 is a plan view showing the second device transfer apparatus in the first embodiment of the present invention.

FIG. 45 is a cross-sectional view showing a pushing apparatus in a second embodiment of the present invention.

FIG. 46 is a view showing the action of the pushing apparatus shown in FIG. 45.

FIG. 47 is a cross-sectional view showing a pushing apparatus in a third embodiment of the present invention.

FIG. 48 is a view showing the action of the pushing apparatus shown in FIG. 47.

FIG. 49 is a cross-sectional view showing a pushing apparatus in a fourth embodiment of the present invention.

FIG. 50 is a view showing the action of the pushing apparatus shown in FIG. 49.

FIG. 51 is a cross-sectional view showing a pushing apparatus in a fifth embodiment of the present invention.

FIG. 52 is a view showing the action of the pushing apparatus shown in FIG. 51.

FIG. 53 is a cross-sectional view showing a pushing apparatus in a sixth embodiment of the present invention.

FIG. 54 is a view showing the action of the pushing apparatus shown in FIG. 53.

FIG. 55 is a cross-sectional view showing a pushing apparatus in a seventh embodiment of the present invention.

FIG. 56 is a view showing the action of the pushing apparatus shown in FIG. 55.

### DESCRIPTION OF EMBODIMENTS

Below, embodiments of the present invention will be explained based on the drawings.

### First Embodiment

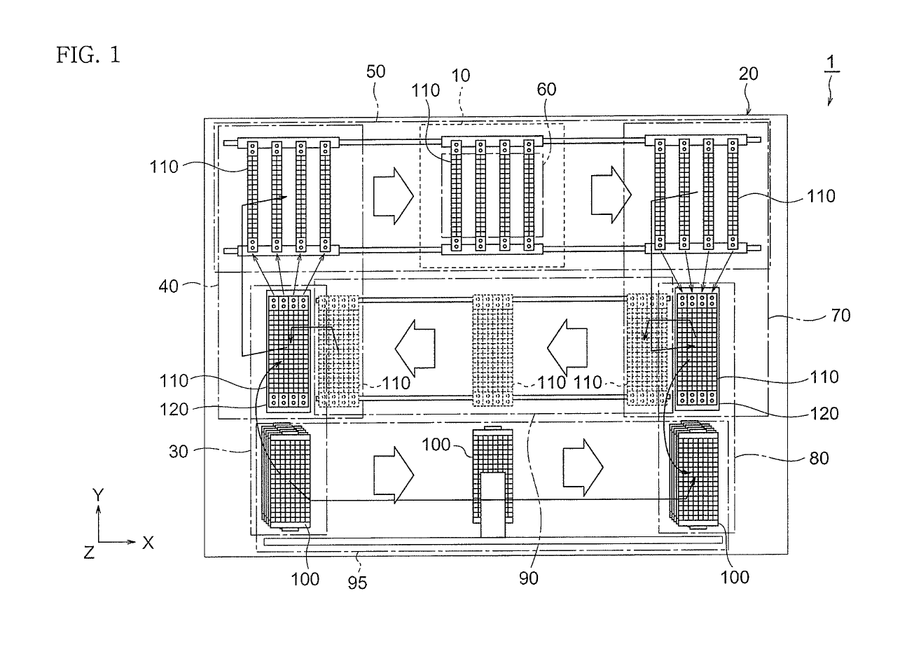

FIG. 1 is a schematic plan view showing the overall configuration of an electronic device test apparatus in the present embodiment.

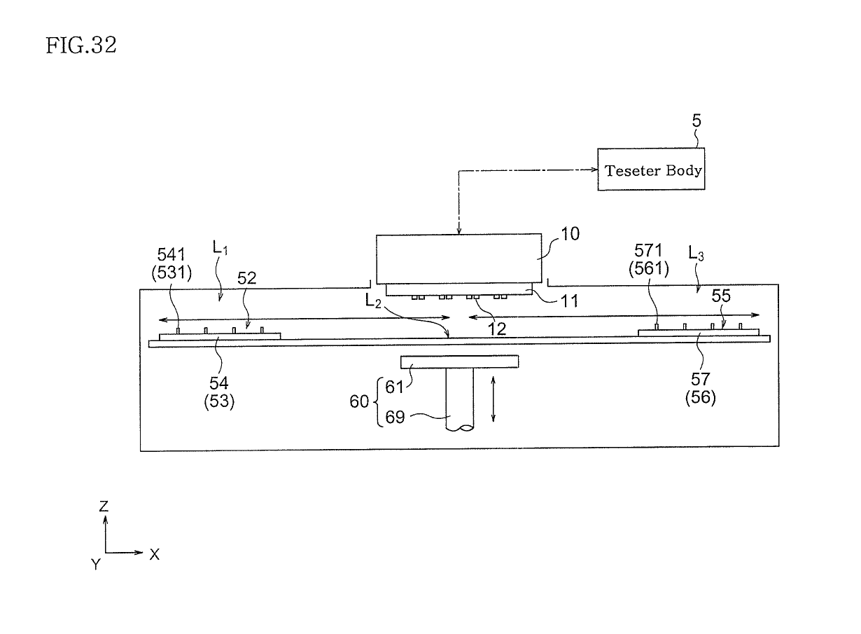

The electronic device test apparatus 1 in the present embodiment is a apparatus which tests semiconductor integrated circuit devices and other devices under test (DUT). As shown in FIG. 1, it comprises: a handler 20 which handles the DUTs; a test head 10 which is electrically connected to the DUTs via a HIFIX 11 (see FIG. 32) at the time of a test; and a tester body 5 which runs the tests on the DUTs (see FIG. 32).

The handler 20 in the present embodiment, as shown in FIG. 1, comprises a first device transfer apparatus 30, a first interval changing apparatus 40, a plate moving apparatus 50, a pushing apparatus 60 (electronic device pushing apparatus), a second interval changing apparatus 70, a second device transfer apparatus 80, a plate return apparatus 90, and a tray return apparatus 95. It transfers a plurality of DUTs from a single customer tray 100 to a plurality of (in the present example, four) contact plates 110 all at once. The DUTs are handled inside the handler 20 in a state with the DUTs held in the contact plates 110.

Referring to FIG. 1 while explaining in general the movement of the contact plates 110 in the handler 20, first, the first device transfer apparatus 30 transfers a plurality of DUTs from a single customer tray 100 to four contact plates 110.

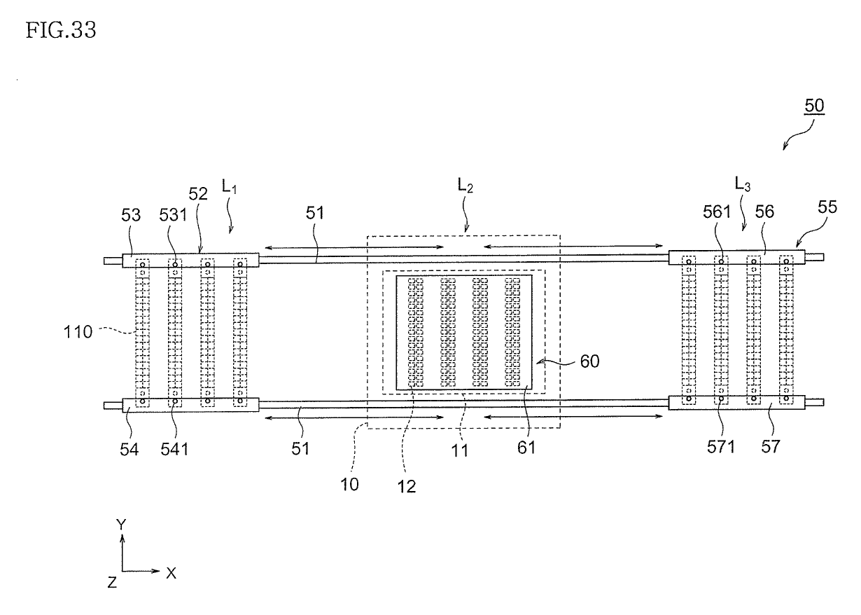

Next, the first interval changing apparatus 40 increases the intervals between the contact plates 110 while transferring contact plates 110 from the first device transfer apparatus 30 to the plate moving apparatus 50. Note that, the intervals between the contact plates 110 are increased so as to secure the regions necessary for interconnects etc. between sockets 12 on the HIFIX 11 (see FIG. 33).

Next, the plate moving apparatus 50 feeds the contact plates 110 to the pushing apparatus 60. The pushing apparatus 60 pushes the DUTs held in the contact plates 110 into the sockets 12 on the HIFIX 11 which is mounted at the test head 10, then the tester body 5 tests the DUTs through the test head 10 and the HIFIX 11.

The finished tested contact plates 110 are ejected by the plate moving apparatus 50 from the pushing apparatus 60, then the second interval changing apparatus 70 decreases the intervals between the contact plates 110 while transferring the contact plates 110 from the plate moving apparatus 50 to the second device transfer apparatus 80. Next, the second device transfer apparatus 80 transfers the DUTs from the contact plates 110 to a customer tray 100.

Note that, the used contact plates 110 are returned by the plate return apparatus 90 from the second device transfer apparatus 80 to the first device transfer apparatus 30. On the other hand, a customer tray 100 emptied of DUTs is returned by the tray return apparatus 95 from the first device transfer apparatus 30 to the second device transfer apparatus 80.

Before explaining details of the parts of the handler 20, the configurations of a customer tray 100 and contact plates 110 will be explained.

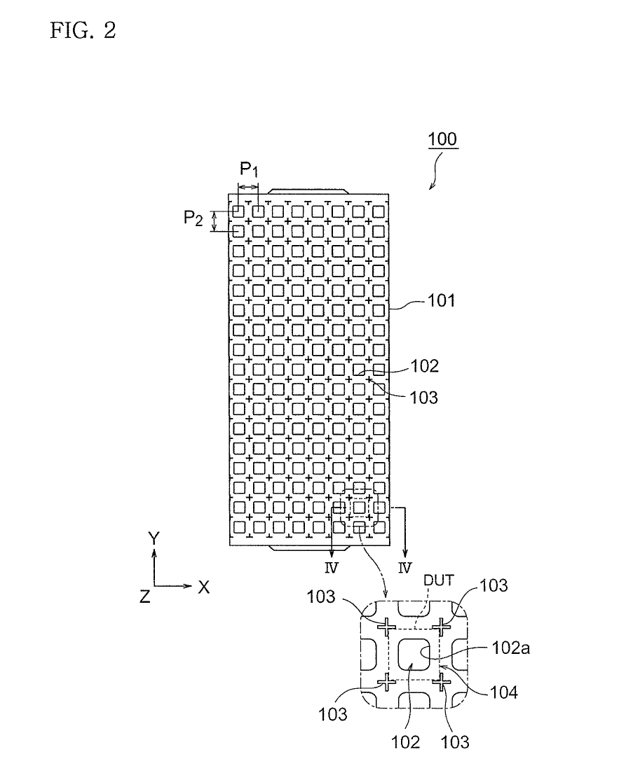

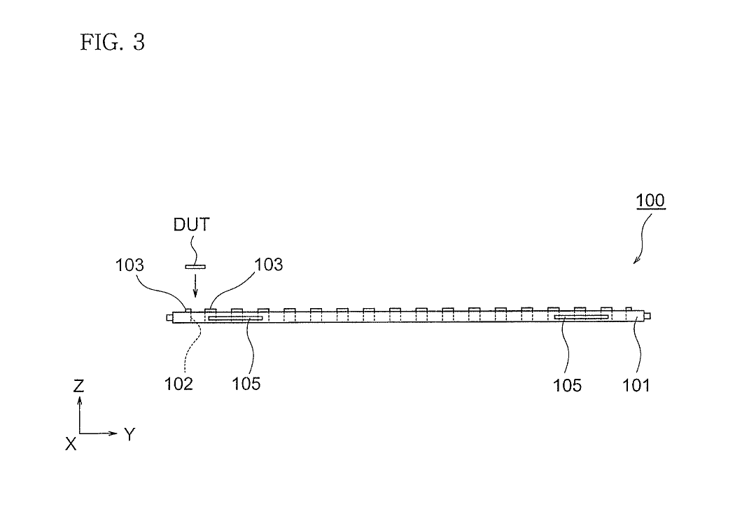

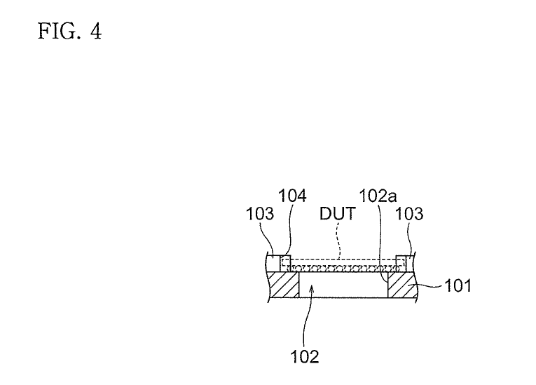

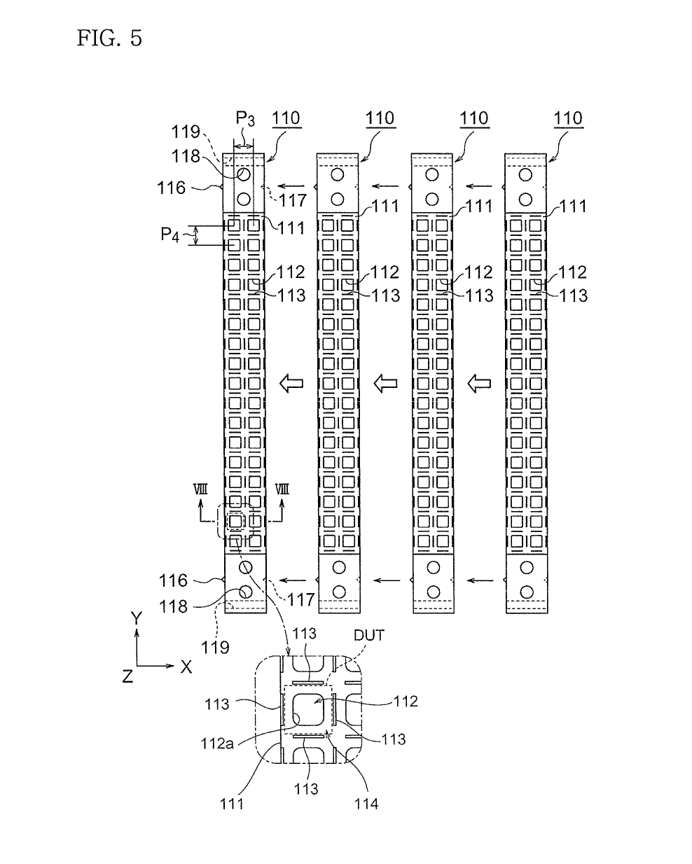

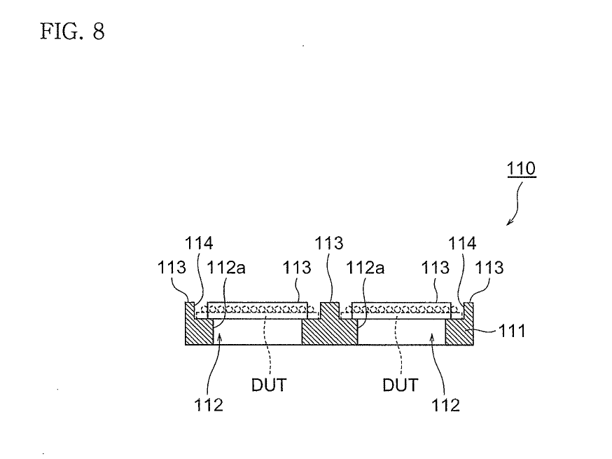

FIG. 2 and FIG. 3 are a plan view and side view of a customer tray in the present embodiment, FIG. 4 is a cross-sectional view along the line IV-IV of FIG. 2, FIG. 5 to FIG. 7 are a plan view and side view showing contact plates in the present embodiment, and FIG. 8 is a cross-sectional view along the line VIII-VIII of FIG. 5.

As shown in FIG. 2 to FIG. 4, a customer tray 100 in the present embodiment comprises a flat plate-shaped tray body 101. A large number (in the present example, 136) through holes 102 are formed on the main surface of this tray body 101.

The large number of through holes 102 are arranged with a pitch in the X-direction of P₁ and a pitch in the Y-direction of P₂ in a matrix shape (in the present example, eight rows and 17 columns). The through holes 102 have substantially rectangular openings 102a.

Approximately cross-shaped ribs 103 are upright provided near the four corners of each opening 102a. Due to the four ribs 103 which surround the opening 102a, a first holding part 104 is defined. The inside of this first holding part 104 is designed to be able to hold a DUT. Further, engagement holes 105 with which first arms of the device transfer apparatuses 30 and 80 engage are formed at the both side surfaces of the tray body 101.

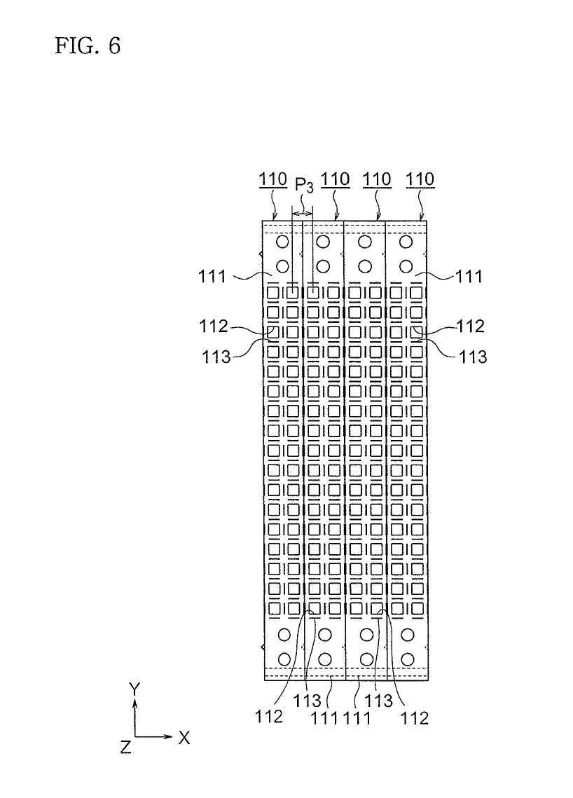

On the other hand, the contact plates 110 in the present embodiment, as shown in FIG. 5 to FIG. 8, comprises strip-shaped plate bodies 111. As shown in FIG. 5, one side surface of each plate body 111 is formed with projecting parts 116, while the other side surface is formed with recessed parts 117. The projecting parts 116 of one contact plate 110 can be fit into the recessed parts 117 of another contact plate 110 so as to, as shown in FIG. 6, couple the contact plates 110 with each other.

The main surface of each plate body 11 is formed with a large number of (in the present example, 34) through holes 112. These through holes 112 are arranged with a pitch in the X-direction of P₃ and a pitch in the Y-direction of P₄ in a matrix shape (in the present example, two rows and 17 columns). Further, in the present embodiment, as shown in FIG. 6, even if coupling contact plates 110, the pitch between the through holes 112 of the adjoining contact plates 110 becomes P₃.

The through holes 112 have approximately rectangular openings 112a. Ribs 113 are upright provided at the four directions of each opening 112a. Due to the four ribs 113 which surround the opening 112a, a second holding part 114 is defined. The inside of this second holding part 114 is designed to be able to hold a DUT.

In the present embodiment, the pitch P₁ in the X-direction of the first holding parts 104 at the customer tray 100 and the pitch P₃ in the X-direction of the second holding parts 114 at the contact plate 110 are substantially the same (P₁=P₃). Similarly, the pitch P₂ in the Y-direction of the first holding parts 104 at the customer tray 100 and the pitch P₄ in the Y-direction of the second holding parts 114 at the contact plate 110 are substantially the same (P₂=P₄).

Therefore, in the present embodiment, as shown in FIG. 6, by coupling four contact plates 110, the number of the second holding parts 114 becomes the same as the number of the first holding parts 104 at one customer tray 100, and the first holding parts 104 and the second holding parts 114 are arrayed the same. For this reason, by laying four contact plates 110 over a single customer tray 100 and then inverting them, a large number of (in this example, 136) DUTs can be simultaneously transferred between the customer tray 100 and the contact plates 110.

Note that, the number of contact plates which correspond to one customer tray is not particularly limited. Further, it is also possible to transfer DUTs all together from M number of customer trays to N number of contact plates (where, M and N are natural numbers and M<N). Furthermore, the number of the first holding parts which are formed at a customer tray and the numbers of the second holding parts which are formed at the contact plates are also not particularly limited.

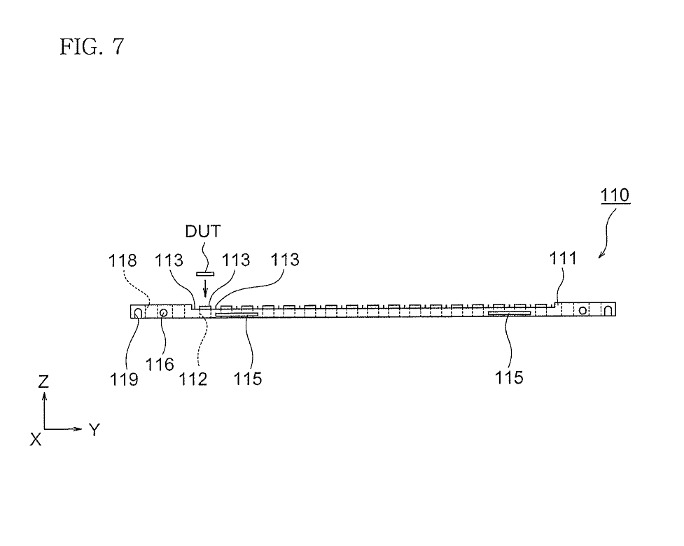

As shown in FIG. 7, grooves 119 in which shafts 123 of a later explained reinforcing plate 120 are to be inserted are formed at the back surface of each plate body 111. Further, as shown in the drawing, engagement holes 115 with which second arms of the device transfer apparatuses 30 and 80 engage are formed at the both side surfaces of the plate body 111. Furthermore, as shown in FIG. 5, insertion holes 118 in which holding pins of the plate moving apparatus 50 are to be inserted are formed near the both ends of the plate body 111.

Below, the detailed configuration of the parts of the handler 20 in the present embodiment will be explained.

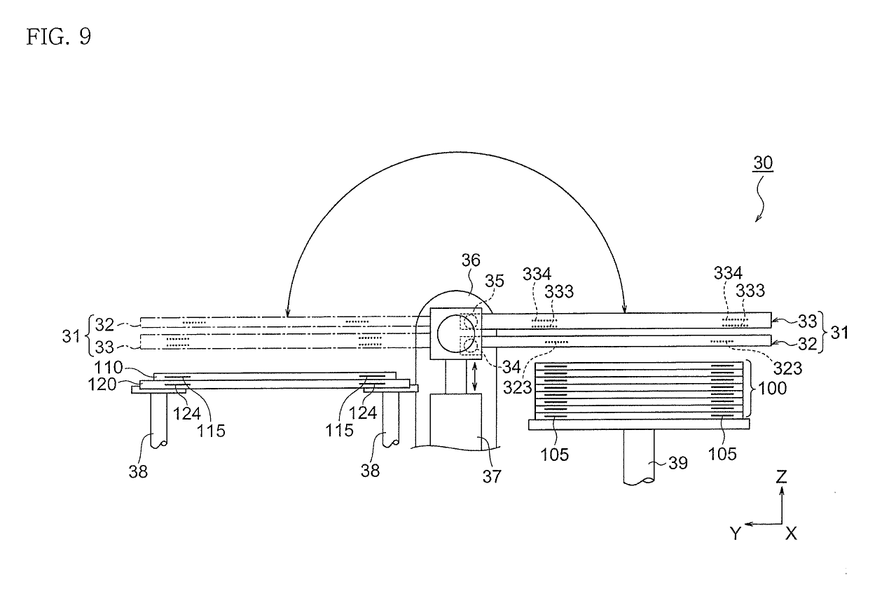

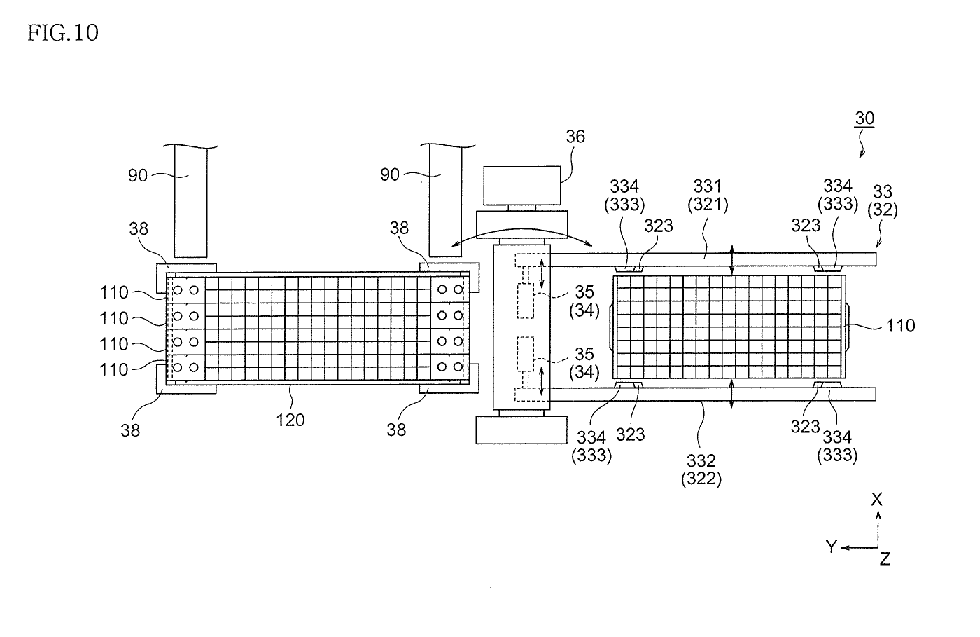

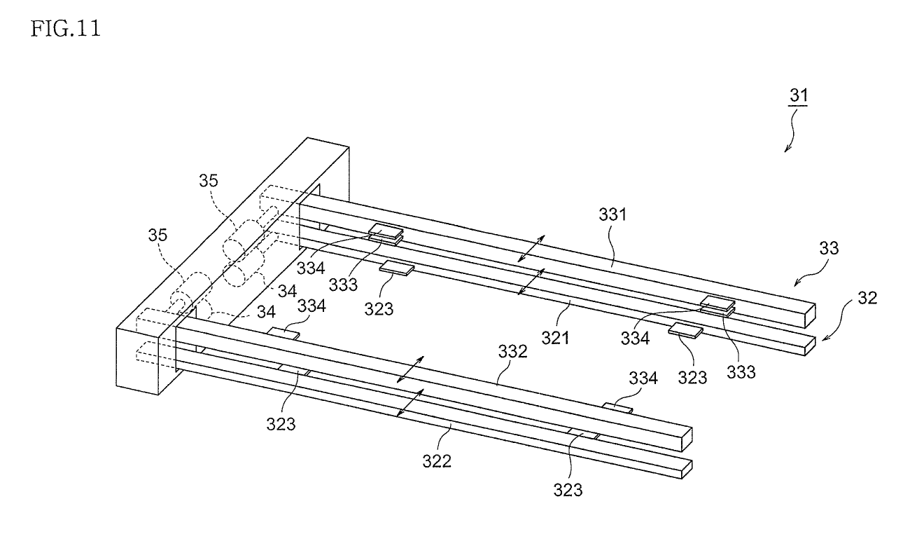

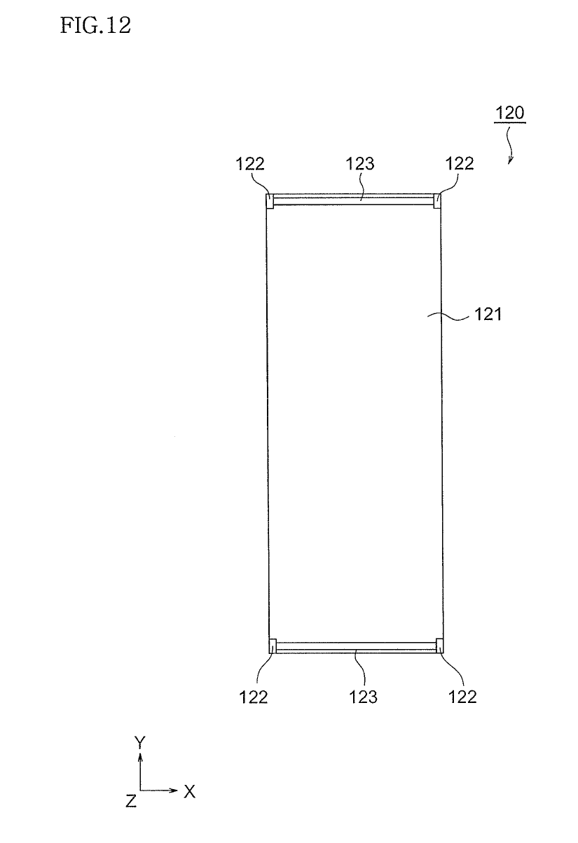

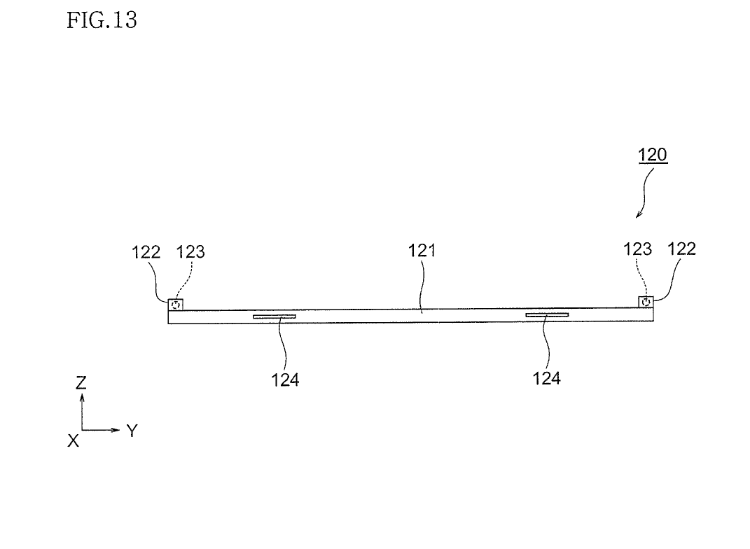

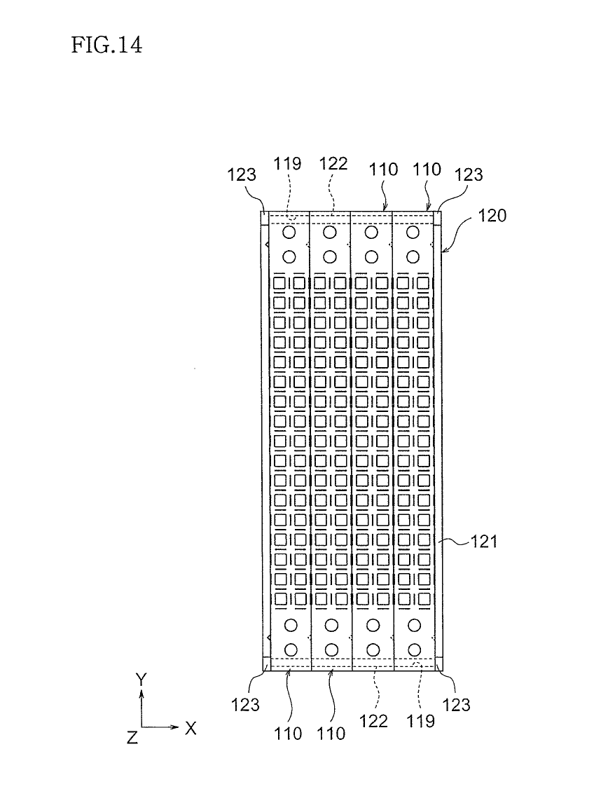

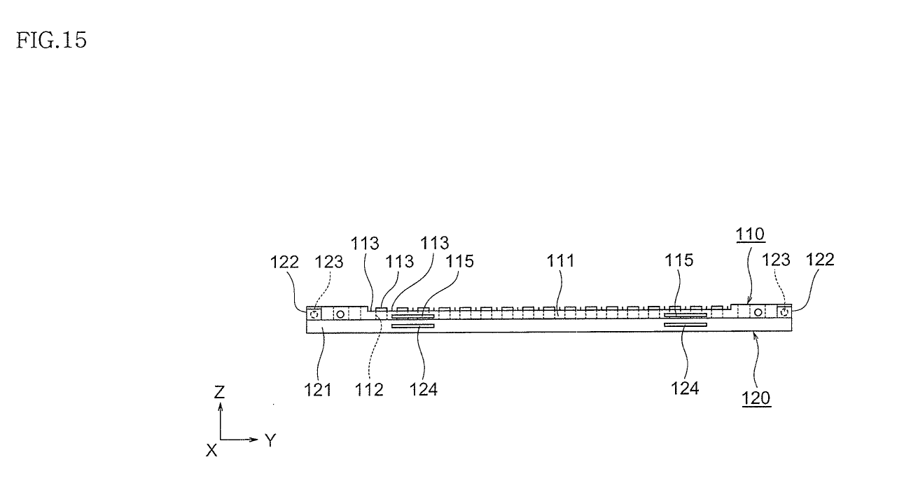

FIG. 9 and FIG. 10 are a side view and a plan view of a first device transfer apparatus in the present embodiment, FIG. 11 is a perspective view showing a holding mechanism of the first device transfer apparatus shown in FIG. 9, FIG. 12 and FIG. 13 are a plan view and a side view of a reinforcing plate in the present embodiment, and FIG. 14 and FIG. 15 are a plan view and a side view showing the state where contact plates are carried on a reinforcing plate.

The first device transfer apparatus 30 of the handler 20, as shown in FIG. 9 and FIG. 10, comprises: a holding mechanism 31 which holds a customer tray 100 and contact plates 110 superimposed; an inversion mechanism 36 which inverts the holding mechanism 31; and an elevating mechanism 37 which moves the inversion mechanism 36 up and down.

Note that, this first device transfer apparatus 30 overlaps and inverts the contact plates 110 and customer tray 100 in the state with the contact plates 110 carried on the reinforcing plate 120 shown in FIG. 12 to FIG. 15. This reinforcing plate 120 can carry four contact plates 110. Blocks 122 are provided at the two top and two bottom ends. These blocks 122 are bridged by shafts 123. The shafts 123 are designed to be able to be inserted in grooves 119 which are formed at the back surfaces of the contact plates 110. Further, engagement holes 124 with which a second arm 33 of the first device transfer apparatus 30 can engage are formed at the both side surfaces of this reinforcing plate 120. Note that, in the later explained second device transfer apparatus 80 as well, a plate similar to this reinforcing plate 120 is used.

The holding mechanism 31 of the first device transfer apparatus 30 comprises: a first arm 32 which grips a customer tray 100; and a second arm 33 which is arranged substantially parallel to this first arm 32 and which grips the four contact plates 110 and reinforcing plate 120.

As shown in FIG. 9 to FIG. 11, the first arm 32 has a pair of arm members 321 and 322 which are arranged to face each other across a predetermined interval. Holding tabs 323 which can engage with engagement holes 105 of a customer tray 100 project from the inside surfaces of these arm members 321 and 322. This pair of arm members 321 and 322 are designed to be able to approach each other or move away from each other by two first operating cylinders 34. The pair of arm members 321 and 322 grip a customer tray 100 between them, whereby the first arm 32 holds the customer tray 100.

Note that, as shown in FIG. 9, customer trays 100 are set into the first device transfer apparatus 30 in a stacked state. An elevator 39 is used so that the topmost level customer tray 100 is positioned at a predetermined height. The first arm 32 grips the customer tray 100 which is positioned at this topmost level.

On the other hand, the second arm member 33 also has a pair of arm members 331 and 332 which are arranged to face each other across a predetermined interval. Holding tabs 333 and 334 which can engage with engagement holes 115 and 124 of contact plates 110 and the reinforcing plate 120 project from the inside surfaces of these arm members 331 and 332. This pair of arm members 331 and 332 of the second arm 33 are designed to be able to approach each other or move away from each other by two operating cylinders 35. This second arm 33 grips the contact plates 110 and reinforcing plate 120 which are supported on the support table 38 by the pair of arm members 331 and 332 so as to grip the four contact plates 110 and reinforcing plate 120.

The inversion mechanism 36 of the first device transfer apparatus 30 is designed to be able to rotate the holding mechanism 31 by 180 degrees by a motor etc. Further, the elevating mechanism 37 is designed to be able to move the holding mechanism 31 and the inversion mechanism 36 up or down by an air cylinder etc.

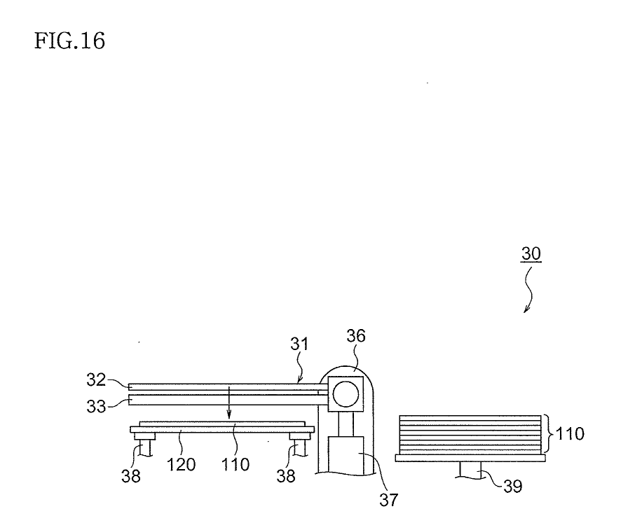

Next, the operation of the first device transfer apparatus 30 explained above will be explained. FIG. 16 to FIG. 24 are views for explaining the operation of the first device transfer apparatus in the present embodiment.

First, as shown in FIG. 16, the elevating mechanism 37 downward moves the holding mechanism 31 which is positioned above the reinforcing plate 120 and contact plates 110 supported on the support table 38.

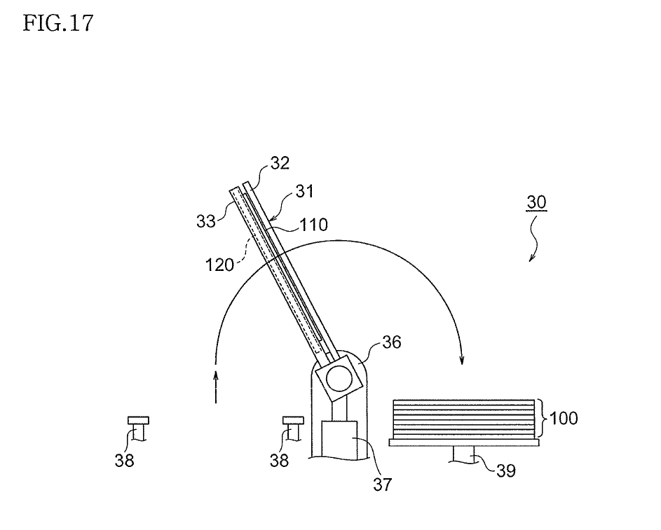

Next, the holding mechanism 31 uses the second arm 33 to grip the four contact plates 110 and the reinforcing plate 120, then, as shown in FIG. 17, the elevating mechanism 37 moves the holding mechanism 31 upward and the inversion mechanism 36 rotates the holding mechanism 31 by 180 degrees.

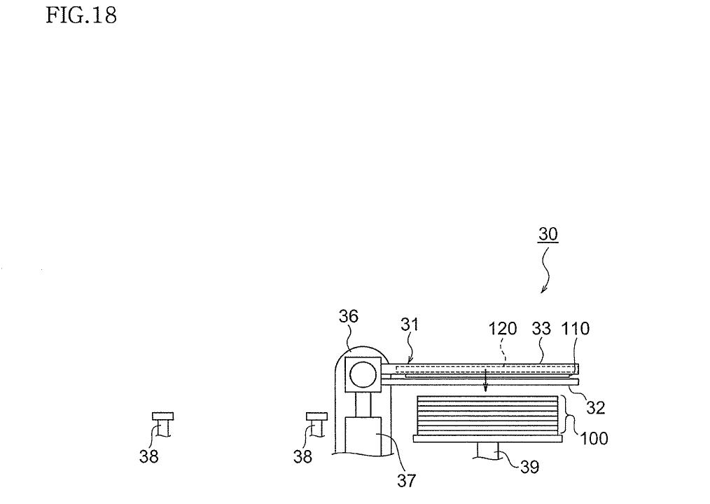

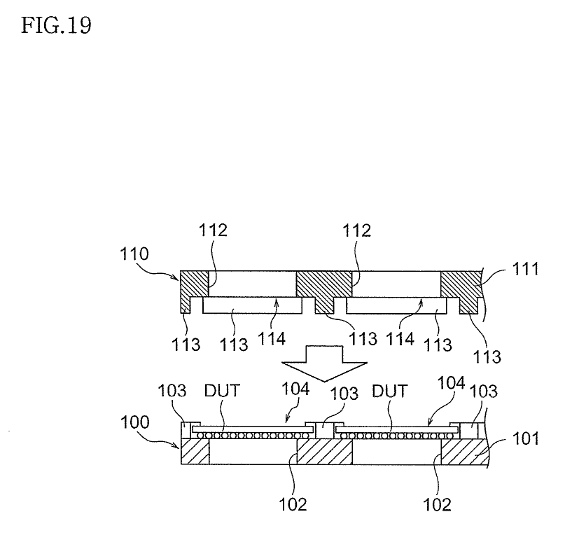

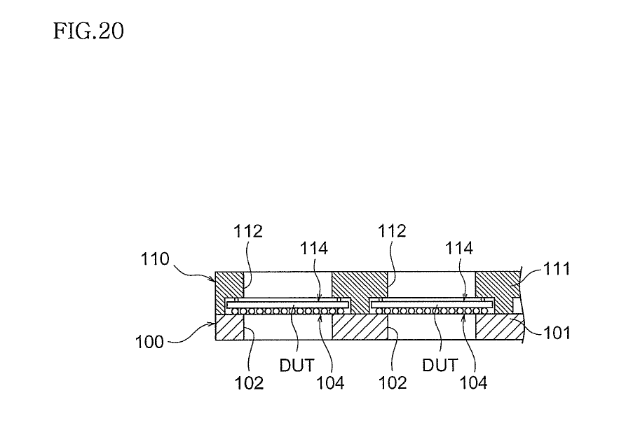

Next, as shown in FIG. 18, the elevating mechanism 37 moves the holding mechanism 31 downward and, as shown in FIG. 19 and FIG. 20, covers the contact plates 110 over the customer tray 100.

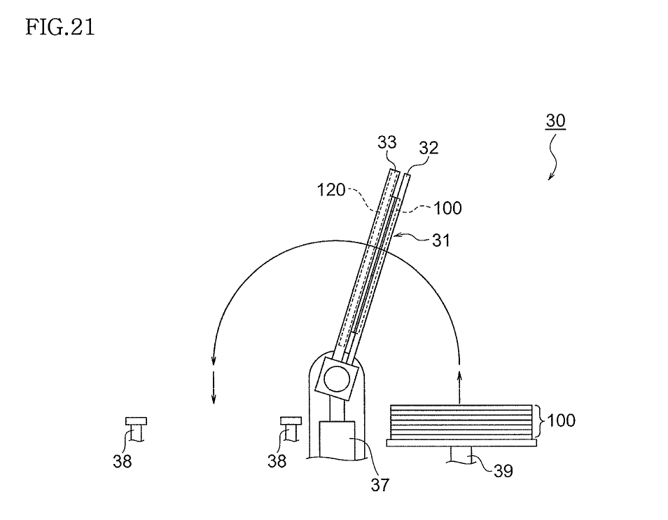

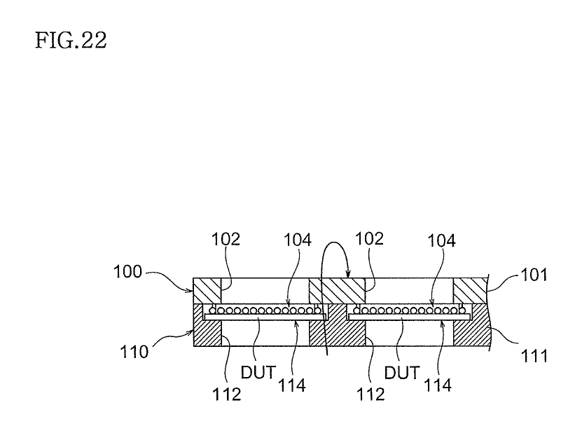

Next, the holding mechanism 31 grips the customer tray 100 by the first arm 32, then, as shown in FIG. 21, the elevating mechanism 37 moves the holding mechanism 31 upward and the inversion mechanism 36 rotates the holding mechanism 31 again by 180 degrees. Due to this rotation, as shown in FIG. 22, all DUTs which were held in the first holding parts 104 of one customer tray 100 are placed all at once in the second holding parts 114 of the four contact plates 110.

Next, the elevating mechanism 37 moves the holding mechanism 31 downward, the reinforcing plate 120 is placed on the support table 38, and the second arm 33 releases the reinforcing plate 120 and the contact plates 110.

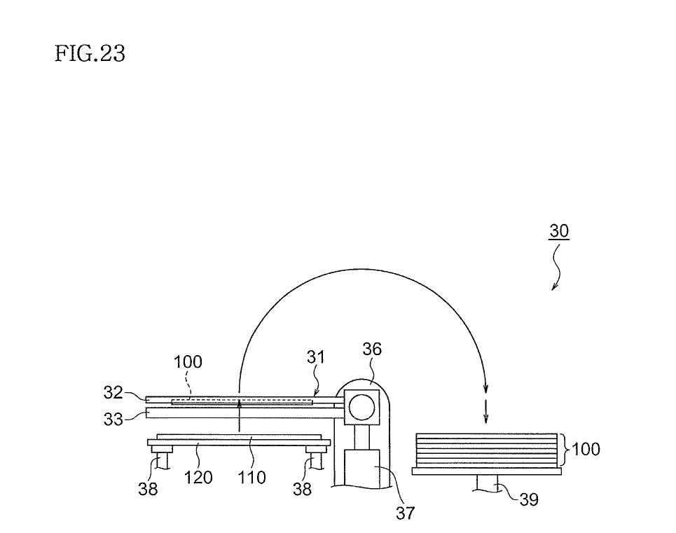

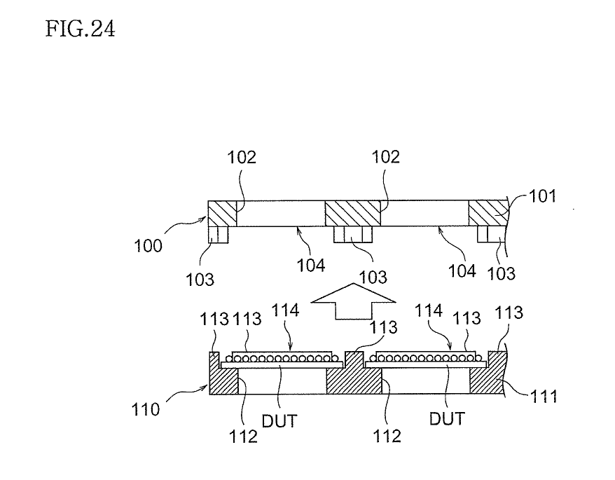

Next, as shown in FIG. 23, the elevating mechanism 37 moves the holding mechanism 31 upward and the inversion mechanism 36 rotates the holding mechanism 31 again by 180 degrees. Due to this, as shown in FIG. 24, the customer tray 100 is detached from above the contact plates 110.

Note that, a customer tray 100 emptied of DUTs, as shown in FIG. 1, is returned from the first device transfer apparatus 30 to the second device transfer apparatus 80 by a tray return apparatus 95 which comprises a pick-and-place apparatus etc.

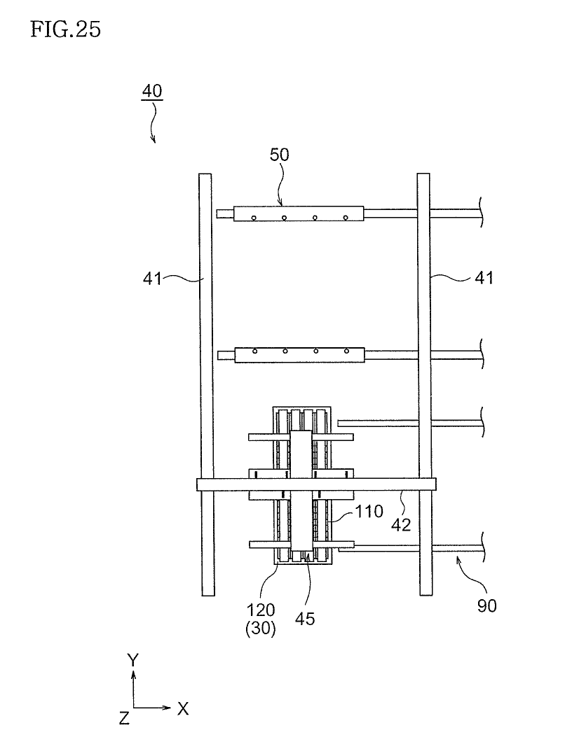

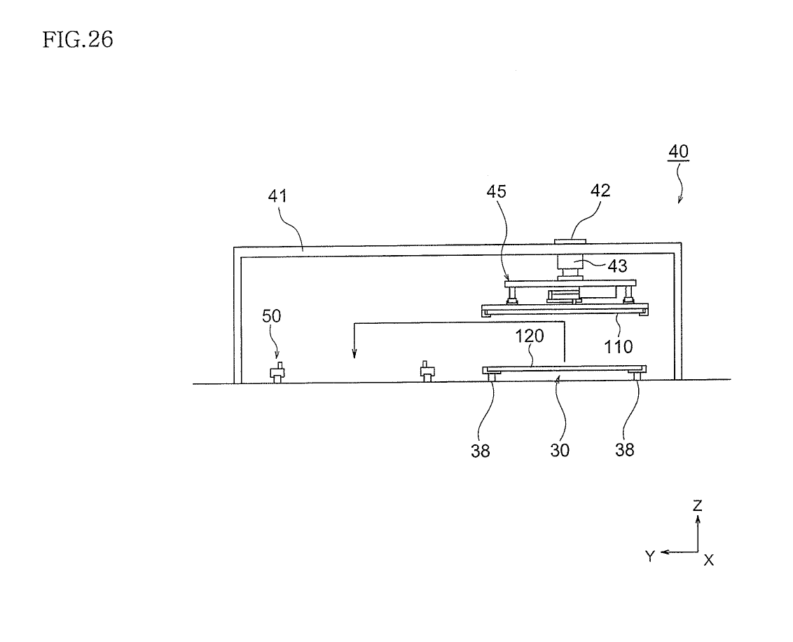

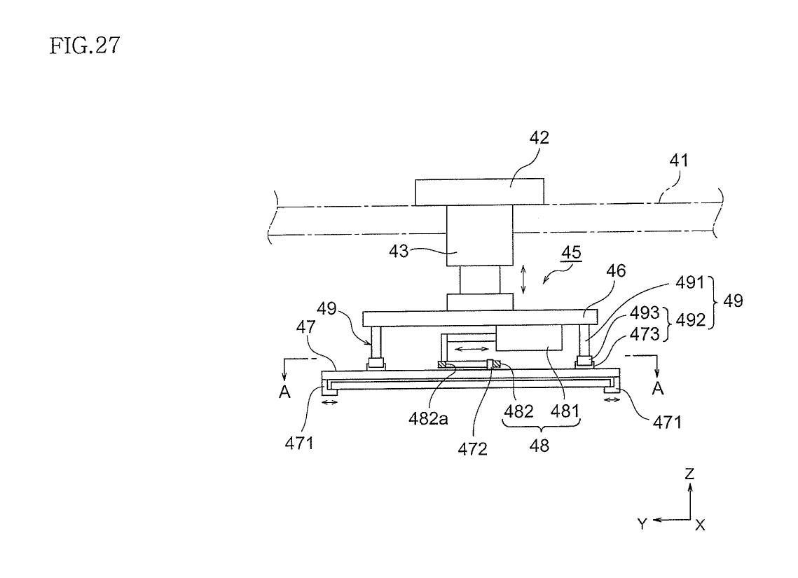

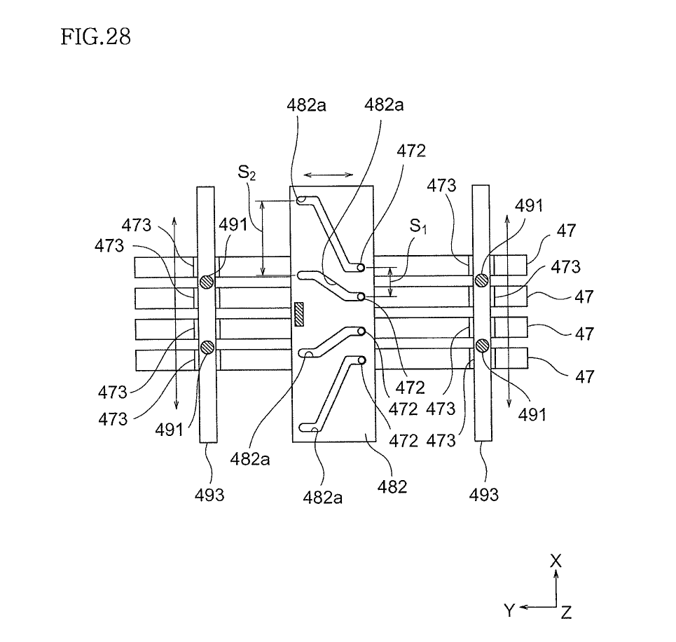

FIG. 25 and FIG. 26 are a plan view and a side view showing the first interval changing apparatus in the present embodiment, while FIG. 27 and FIG. 28 are a side view and a plan view showing a movable head in the first interval changing apparatus.

The first interval changing apparatus 40 of the handler 20, as shown in FIG. 25 and FIG. 26, comprises a pair of Y-direction rails 41, a movable arm 42, an elevator actuator 43, and a movable head 45.

The Y-direction rails 41 extend between the first device transfer apparatus 30 and the plate moving apparatus 50 along the Y-direction. The Y-direction rails 41 support the movable arm 42. The movable arm 42 is designed to be able to move in the Y-direction. Further, the movable arm 42 is provided with an elevator actuator 43 which comprises an air cylinder etc. This elevator actuator 43 is designed to be able to move in the X-direction. The movable head 45 is attached at the front end of this elevator actuator 43. The movable head 45 is therefore designed to be able to move up and down by the elevator actuator 43.

The movable head 45, as shown in FIG. 27 and FIG. 28, comprises: a base member 46; holding members 47 which hold the contact plates 110; an interval changing mechanism 48 which changes the intervals between the holding members 47; and a coupling mechanism 49 which couples the base member 46 and the holding members 47.

The base member 46 is fastened to the front end of the drive shaft of the elevator actuator 43. Further, this base member 46 has four holding members 47 attached to it through the interval changing mechanism 48 and coupling mechanism 49.

The holding members 47 have tab shapes corresponding to the individual contact plates 110. Grippers 471 for gripping the contact plates 110 are provided at the both ends in openable/closable manners.

Note that, the number of the holding members 47 which the movable head 45 has is not limited to the above number. For example, the number is set in accordance with the number of contact plates 110 corresponding to one customer tray 100.

The interval changing mechanism 48 comprises: an air cylinder 481 which is provided at the base member 46; a cam plate 482 which is fastened to a front end of a drive shaft of this air cylinder 481; and cam followers 472 which are respectively provided on the top surfaces of the contact plates 110.

As shown in FIG. 28, four cam grooves 482a are formed on the cam plate 482. These cam grooves 482a have pitches which continuously change between the relatively narrow first pitch S₁ and the relatively broad second pitch S₂. The four cam grooves 482a have the cam followers 472 which project out from the top surfaces of the contact plates 110 inserted into them in a slidable manner.

Therefore, if the air cylinder 481 makes the drive shaft extend, in FIG. 28, the cam followers 472 slide inside the cam grooves 482a relatively to the right side whereby the pitch between the cam followers 472 is narrowed to the first pitch S₁. In the state where the pitch between the cam followers 472 is the first pitch S₁, the contact plates 110 which are held by the holding member 47 are in close contact with each other.

On the other hand, if the air cylinder 481 makes the drive shaft shorter, in FIG. 28, the cam followers 472 slide inside the cam grooves 482a relatively to the left side whereby the pitch between the cam followers 472 is broadened to the second pitch S₂. If the pitch between the cam followers 472 becomes the second pitch S₂, the array of DUTs which are held in the contact plates 110 correspond to the array of sockets 12 on the HIFIX 11.

The coupling mechanism 49, as shown in FIG. 27, comprises: coupling members 491 which extend downward from the base member 46; and linear guides 492 which are provided at front ends of the coupling members 491. Each of the linear guide 492 comprises: a guide rail 493 which is fastened to the front ends of the coupling members 491; and slide blocks 473 which are provided on the top surfaces of the holding members 47 and which are engaged with the guide rail 493 to be able to slide along the X-direction. Due to this coupling mechanism 49, the holding members 47 are coupled to the base member 46 while allowing change of the interval between holding members 47 by the interval changing mechanism 48.

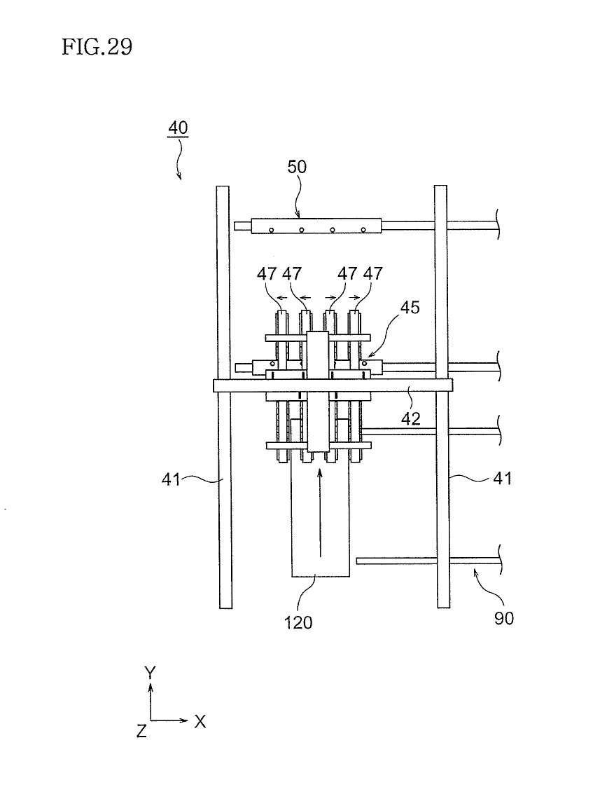

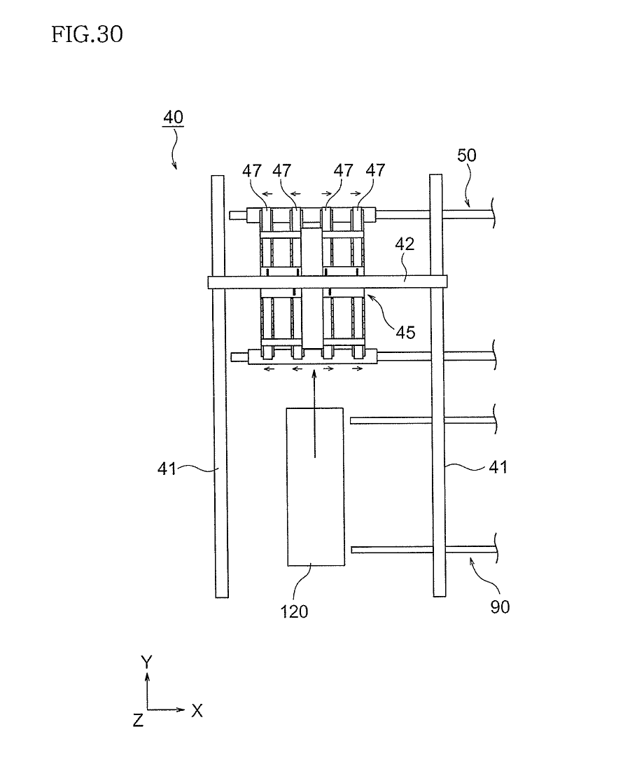

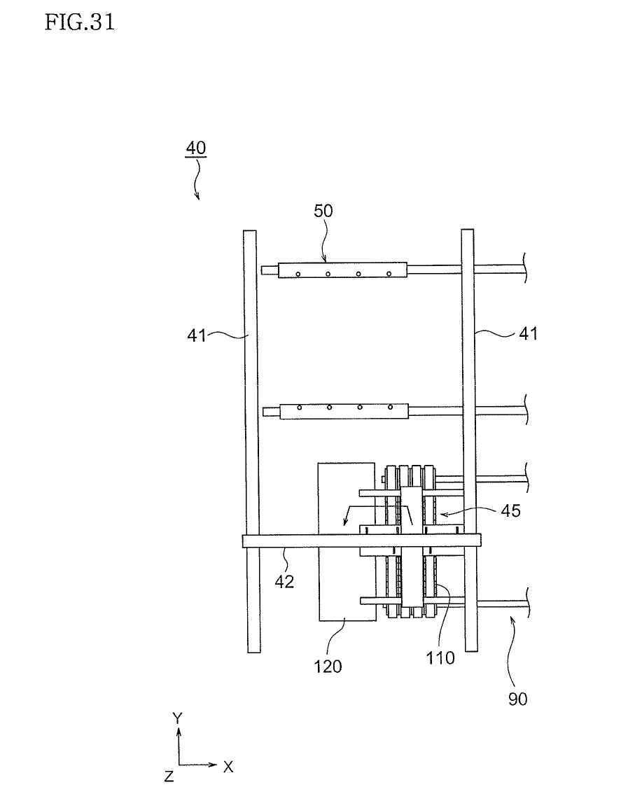

Next, the operation of the first interval changing apparatus 40 explained above will be explained. FIG. 29 and FIG. 30 are plan views showing the conveyance operation of contact plates by the first interval changing apparatus in the present embodiment. FIG. 31 is a plan view showing a setting operation of the contact plates by the first interval changing apparatus in the present embodiment.

First, as shown in FIG. 25, when the movable head 45 picks up four contact plates 110 from the reinforcing plate 120 of the first device transfer apparatus 30, the elevator actuator 43 is used to move the movable head 45 upward.

Next, as shown in FIG. 29, the movable arm 42 moves on the Y-direction rails 41. During this movement, the interval changing mechanism 48 of the movable head 45 broadens the pitch between the cam followers 472 from the first pitch S₁ to the second pitch S₂ to thereby broaden the interval between the holding members 47. As shown in FIG. 30, when the movable head 45 is positioned above the plate moving apparatus 50, the movable arm 42 stops, the elevator actuator 43 moves the movable head 45 downward, and four contact plates 110 are placed on the plate moving apparatus 50. At this time, as the pitch between the cam followers 472 has been changed to the second pitch S₂ by the interval changing mechanism 48 and the interval between the holding members 47 has been broadened, so the array of DUTs which are held in the contact plates 110 corresponds to the array of sockets 12 on the HIFIX 11.

Incidentally, as shown in FIG. 31, the first interval changing apparatus 40 of the present embodiment also encompasses part of the plate return apparatus 90 in its range of operation. For this reason, this first interval changing apparatus 40 can, for example, use a plate return apparatus 90 which comprises a rotary belt etc. so as to move the four contact plates 110 which were returned from the second device transfer apparatus 80 to the reinforcing plate 120 of the first device transfer apparatus 30.

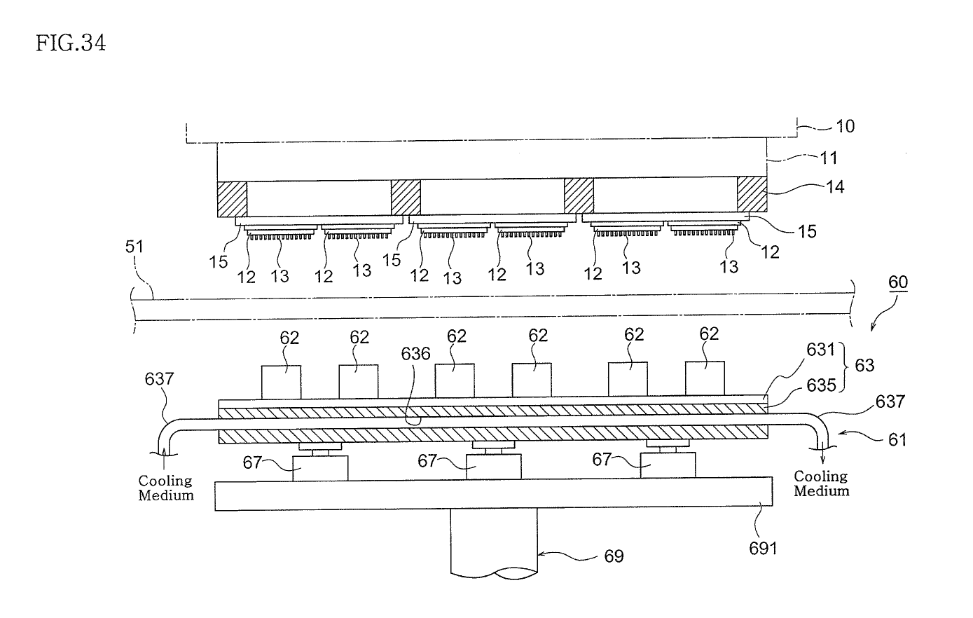

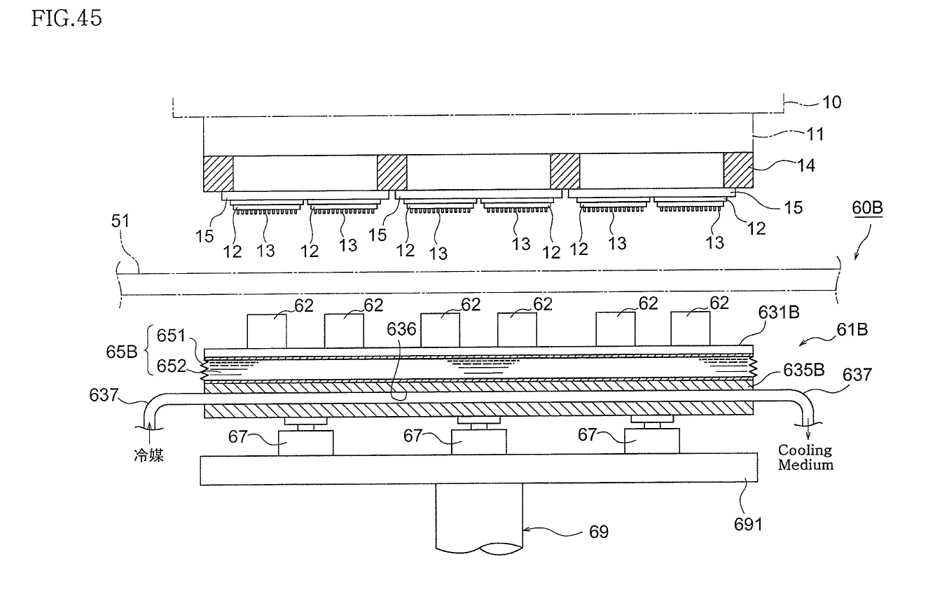

FIG. 32 and FIG. 33 are views showing the plate moving apparatus and the pushing apparatus in the present embodiment, while FIG. 34 is a cross-sectional view showing the pushing apparatus in the present embodiment. Note that, in FIG. 34, to clearly express the configuration of the pushing apparatus, the numbers of socket and pushers are illustrated smaller than in practice. The same is true for the later explained FIG. 45 to FIG. 56 as well.

The plate moving apparatus 50 of the handler 20, as shown in FIG. 32 and FIG. 33, comprises a pair of X-direction rails 51 and two moving members 52 and 55.

A pair of X-direction rails 51 are provided substantially in parallel with each other with a predetermined distance and are provided between a first position L₁ where contact plates 110 are received from the first interval changing apparatus 40 and a third position L₃ where contact plates 110 are transferred to the second interval changing apparatus 70. A pushing apparatus 60 is provided at the approximate center part of the X-direction rails 51 (second position L₂). The test head 10 approaches the inside of the handler 20 from above so as to face this pushing apparatus 60.

The first moving member 52 comprises a pair of holding members 53 and 54 which are provided so as to be able to slide on the X-direction rails 51 along the X-direction. Four each holding pins 531 and 541 which are able to be inserted into insertion holes 118 of the contact plates 110 are upright provided on the holding member 53 and 54 respectively. Therefore, the first moving member 52 is able to simultaneously hold four contact plates 110.

The second moving member 55 similarly comprises a pair of holding members 56 and 57 which are provided to be able to move on the X-direction rails 51 along the X-direction. Four each holding pins 561 and 571 which are able to be inserted into the insertion holes 118 of the contact plates 110 are upright provided on the holding members 56 and 57 respectively. Therefore, the second moving member 55 is also able to simultaneously hold four contact plates 110.

Note that, the number of contact plates 110 which the first and second moving members 52 and 55 can simultaneously hold is not particularly limited to the above number. For example, the number is set in accordance with the number of contact plates corresponding to a single customer tray 100.

The first moving member 52 moves the contact plates 110 between the first position L₁ and the second position L₂. On the other hand, the second moving member 55 moves the contact plates 110 between the second position L₂ and the third position L₃. Further, the first moving member 52 and the second moving member 55 can move independently on the X-direction rails 51.

The pushing apparatus 60, as shown in FIG. 34, comprises: a pushing unit 61 which pushes DUTs which are held on the contact plates 110 to the sockets 12; and a Z-axis actuator (moving means) 69 which moves the pushing unit 61 up and down.

The pushing unit 61 in the present embodiment comprises a plurality of pushers 62, a base plate 631, a temperature regulating plate 641, and bellofram cylinders 67.

Each of the pushers 62 comprises a metal prismatic columnar or cylindrical member having a top surface of a shape corresponding to the DUT. On the other hand, the base plate 631 comprises a metal plate member. The plurality of pushers 62 are provided so as to stick out from one of the main surfaces of the base plate 631 and are arranged on the base plate 631 so as to correspond to the arrangement of sockets 12 on the test head 10. The pushers 62 directly contact the individual DUTs when the pushing unit 61 pushes the DUTs to the sockets 12.

The temperature regulating plate 635 is a metal plate which is placed at the bottom side of the base plate 631. A channel 636 through which is run a cooling medium (for example, Fluorinert® made by 3M) which is fed from a chiller (not shown) connected via a pipe 637 is formed inside it. Note that, instead of a cooling medium, it is also possible to run a heating medium through the channel 636 or embed a heater etc. in the temperature regulating plate 635.

In the present embodiment, the plate stack 63 which comprises the base plate 631 and the temperature regulating plate 635 has a rigidity which is set lower relative to the rigidity of the spacing frame 14 of the HIFIX 11 (explained later). Specifically, the base plate 631 or the temperature regulating plate 635 is made thinner, the base plate 631 or the temperature regulating plate 635 is formed with cutaway parts, or the base plate 631 or temperature regulating plate 635 is configured by a low strength material so as to lower the rigidity of the plate stack 63.

Note that, the pushing unit 61 need not be provided with the temperature regulating plate 635. In this case, the base plate 631 alone is given a rigidity which is set lower relative to the rigidity of the spacing frame 14 of the HIFIX 11.

The bellofram cylinders 67 push the base plate 631 by a certain pressure via the temperature regulating plate 635 and can absorb excessive load applied to the DUTs. The bellofram cylinders 67 are fastened to the elevating plate 691 of the Z-direction actuator 69.

This pushing unit 61, as shown in FIG. 33, is arranged between the pair of X-direction rails 51 in the plan view. Even if the Z-direction actuator 69 is used to move the pushing unit 61 up or down, there is no interference between the pushing unit 61 and the X-direction rails 51.

The HIFIX (interface device) 11 is mounted on the top part (in FIG. 34, the bottom part) of the test head 10. This HIFIX 11, as shown in FIG. 34, comprises: a plurality of socket boards 15 on which sockets 12 are mounted; and a spacing frame 14 which holds the plurality of socket boards 15. The sockets 12 have large numbers of contact pins 13 which electrically contact terminals HB of the DUTs and are arranged on the HIFIX 11 to correspond to the DUTs which are held in the four contact plates 110.

In the present embodiment, as explained above, the plate stack 63 of the pushing unit 61 is made thinner etc. so that the rigidity of the spacing frame 14 is set higher relative to the rigidity of the plate stack 63 of the pushing unit 61.

Note that, it is also possible to make the spacing frame 14 thicker or configure the spacing frame 14 by a high strength material so as to set the rigidity of the spacing frame 14 higher relative to the plate stack 63 of the pushing unit 61.

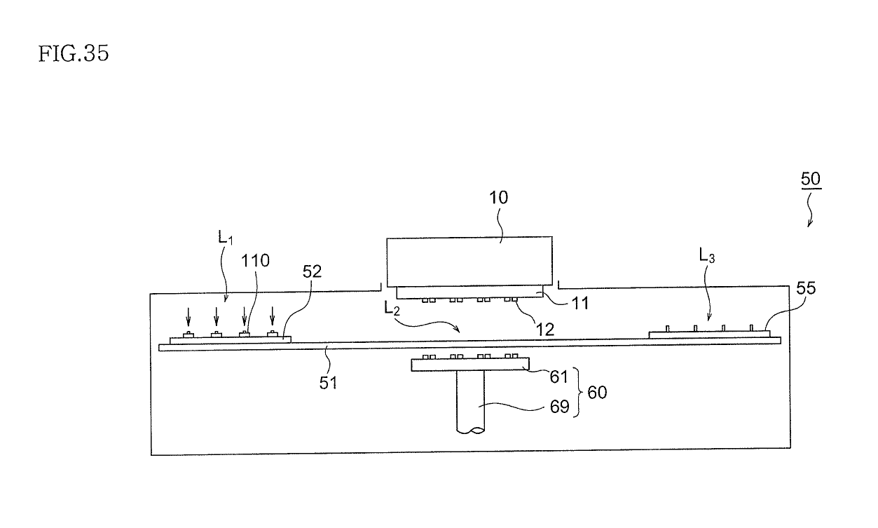

Next, the operation of the plate moving apparatus 50 and pushing apparatus 60 explained above will be explained. FIG. 35 to FIG. 42 are views for explaining the operation of the plate moving apparatus and pushing apparatus in the present embodiment.

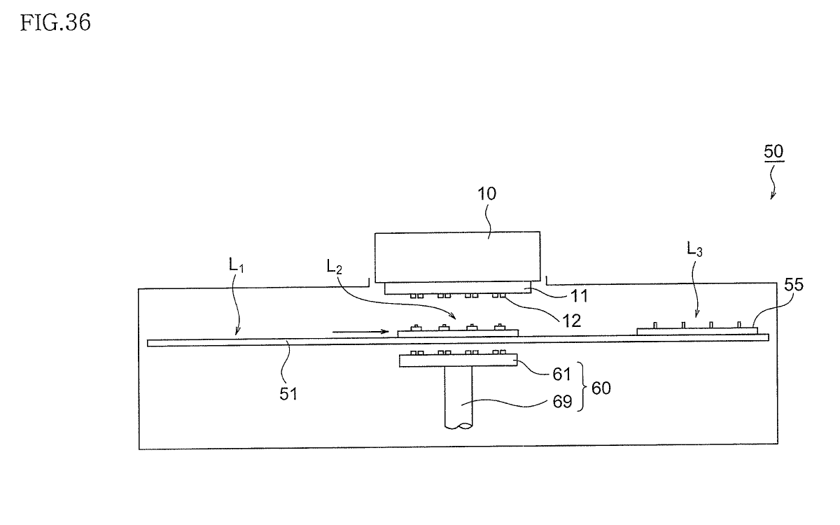

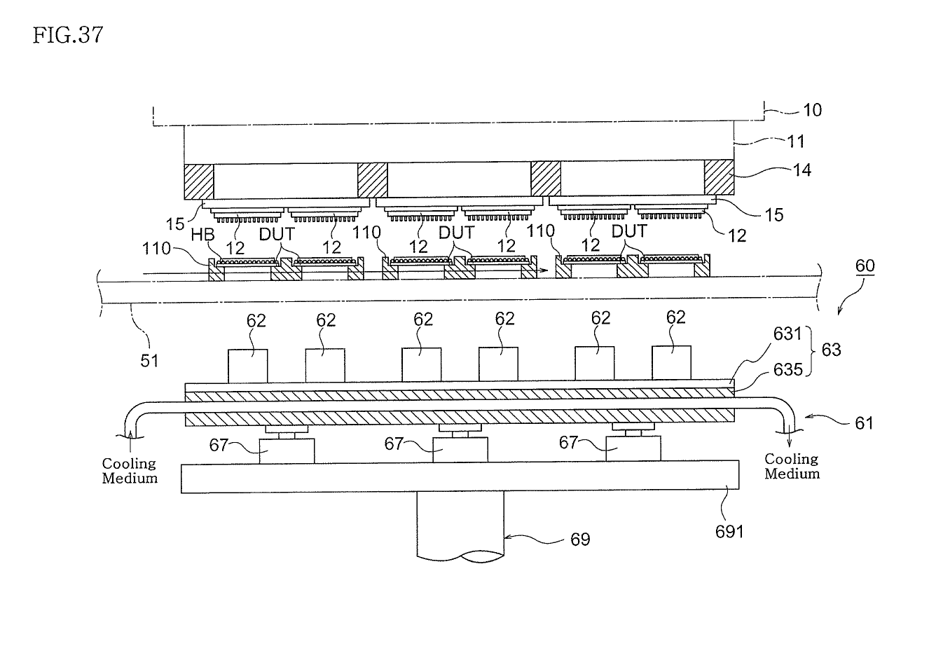

First, as shown in FIG. 35, the first interval changing apparatus 40 places four contact plates 110 on the first moving member 52 which is positioned at the first position L₁ on the X-direction rails 51. Next, as shown in FIG. 36, the first moving member 52 moves from the first position L₁ to the second position L₂ on the X-direction rails 51. Due to the operation of this first moving member 52, as shown in FIG. 37, the contact plates 110 are positioned above the pushing unit 61 of the pushing apparatus 60.

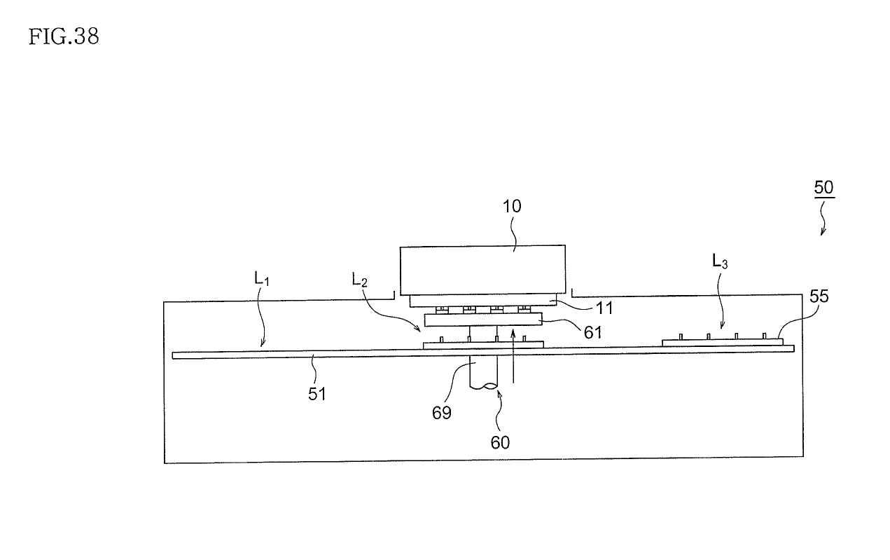

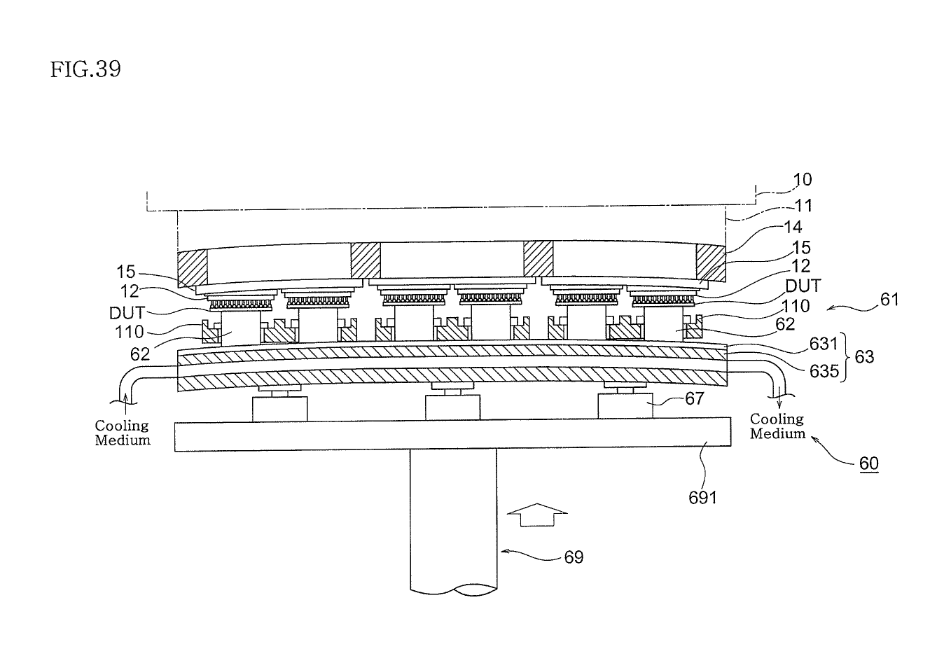

Next, as shown in FIG. 38, the pushing apparatus 60 moves the pushing unit 61 upward by the Z-direction actuator 69 whereby the pushing unit 61 receives the contact plates 110 from the first moving member 52, then the Z-direction actuator 69 further moves pushing unit 61 upward. Due to this, as shown in FIG. 39, the DUTs are lifted up by the pushers 62 of the pushing unit 61 from the contact plates 110 and are pushed to the sockets 12 of the HIFIX 11 whereby the terminals HB of the DUTs and the contact pins 13 of the sockets 12 electrically contact each other. In this state, the tester body 5 inputs and outputs test signals with the DUTs through the test head 10 and HIFIX 11 whereby the DUTs are tested.

As shown in FIG. 39, along with the pushing action of the pushing apparatus 60, the spacing frame 14 of the HIFIX 11 flexes. At this time, in the present embodiment, the rigidity of the plate stack 63 of the pushing unit 61 is set lower relative to the rigidity of the spacing frame 14 of the HIFIX 11, so the plate stack 63 deforms so as to match the flexing of the spacing frame 14. For this reason, the occurrence of poor contact between the terminals HB of the DUTs and the contact pins 13 of the sockets 12 can be suppressed.

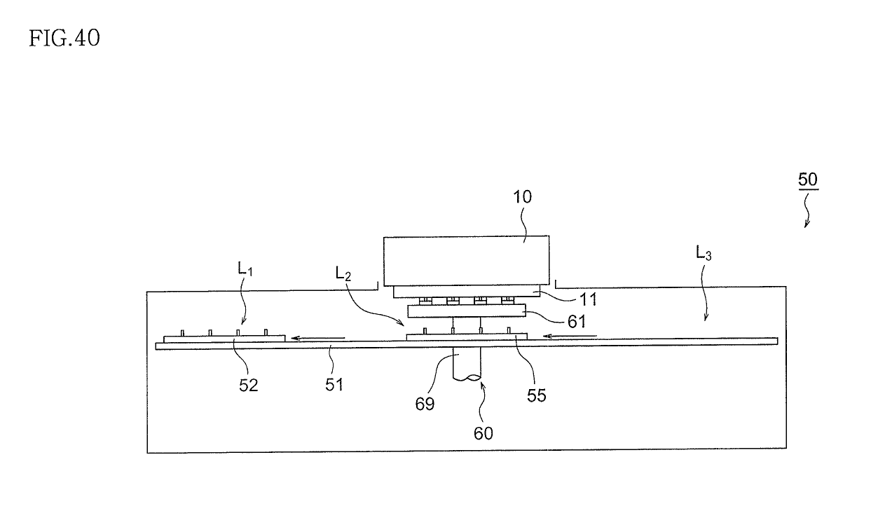

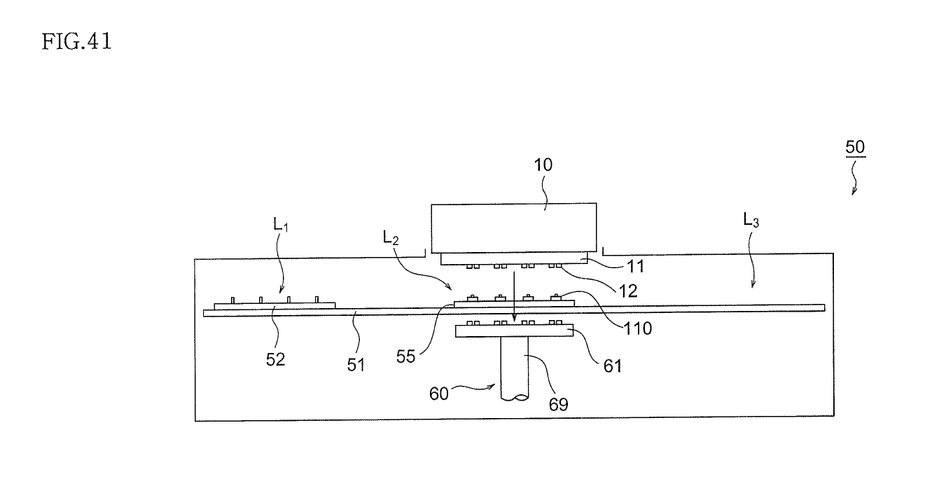

While the tester body 5 is running tests on the DUTs, as shown in FIG. 40, the first moving member 52 retracts from the second position L₂ to the first position L₁ and the second moving member 55 moves from the third position L₃ to the second position L₂. Further, after the DUTs finish being tested, as shown in FIG. 41, the Z-direction actuator 69 of the pushing apparatus 60 moves the pushing unit 61 downward and the second moving member 55 receives the finished tested contact plates 110 from the pushing unit 61.

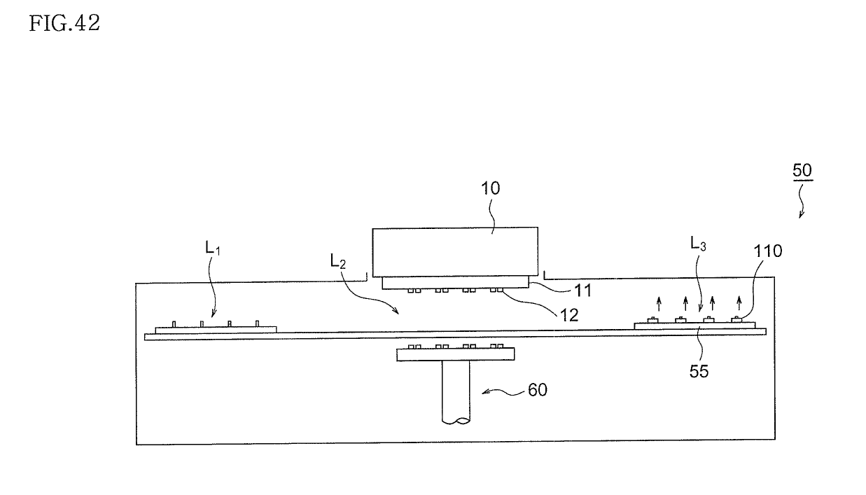

Next, as shown in FIG. 42, the second moving member 55 moves from the second position L₂ to the third position L₃ and the second interval changing apparatus 70 transfers the four contact plates 110 from the second moving member 55 to the second device transfer apparatus 80.

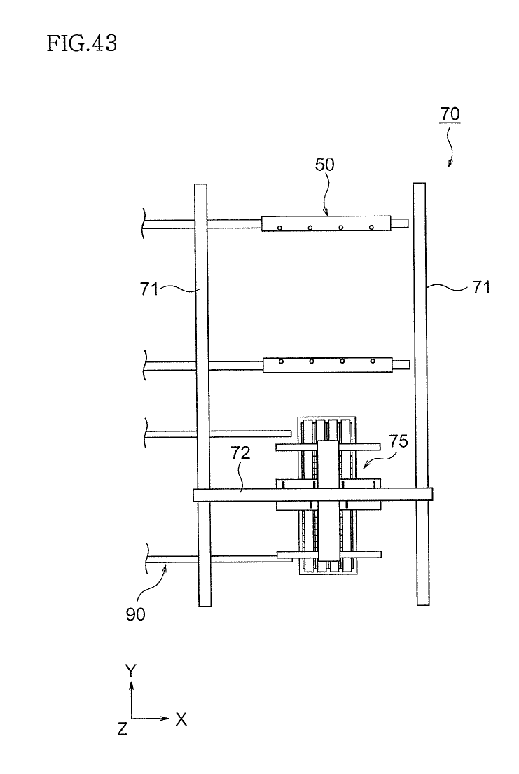

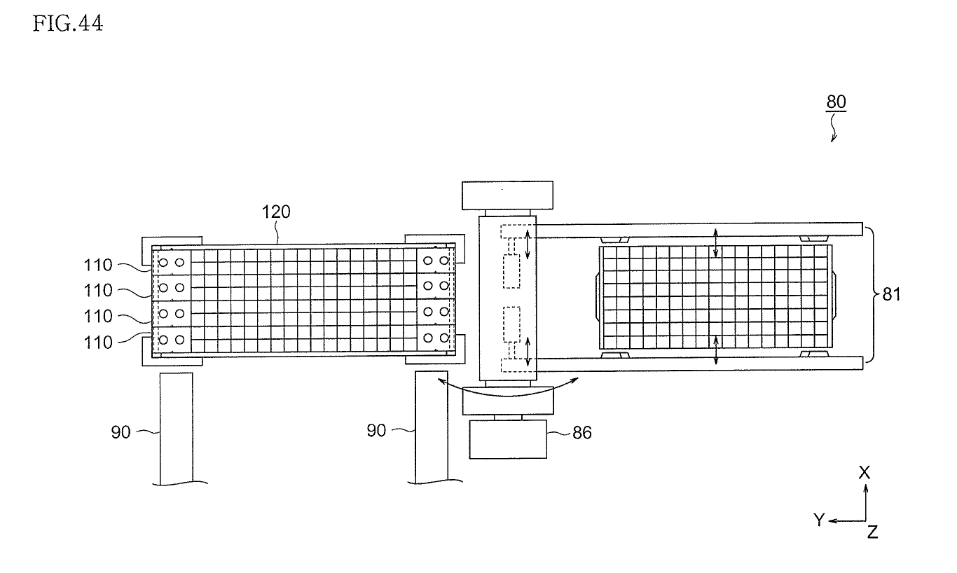

FIG. 43 is a plan view showing a second interval changing apparatus of the present embodiment, while FIG. 44 is a plan view showing a second device transfer apparatus in the present embodiment.

The second interval changing apparatus 70 of the handler 20, as shown in FIG. 43, like the above first interval changing apparatus 40, comprises: a pair of Y-direction rails 71; a movable arm 72 which is supported by the Y-direction rails 71 to be able to move along the Y-direction; an elevator actuator which is supported by the movable arm 72 to be able to move along the X-direction; and a movable head 75 which can be raised or lowered by the elevator actuator.

Further, the movable head 75, like the movable head 45 of the first interval changing apparatus 40, has an interval changing mechanism which changes the intervals between the holding members which hold the contact plates 110. While the movable head 75 moves the contact plates 110 from the plate moving apparatus 50 to the second device transfer apparatus 80, it can reduce the intervals between the contact plates 110.

This second interval changing apparatus 70 reduces the intervals between the four contact plates 110 while transferring the contact plates 110 from the plate moving apparatus 50 to the second device transfer apparatus 80. Further, the second device transfer apparatus 80 overlays a customer tray 100 on the four contact plates 110 and inverts them so that all of the DUTs which were held in the second holding parts 114 of the four contact plates 110 are transferred all together to the first holding parts 104 of the customer tray 100.

Note that, a customer tray 100 emptied of DUTs, as shown in FIG. 1, is returned by the tray return apparatus 95 from the first device transfer apparatus 30 to the second device transfer apparatus 80. On the other hand, the used contact plates 110 are returned by the plate return apparatus 90 from the second device transfer apparatus 80 to the first device transfer apparatus 30.

The customer trays 100 which hold the finished tested DUTs are stored in the second device transfer apparatus 80 in a state stacked. Further, after a predetermined number of customer trays 100 are stored, the customer trays 100 are taken out from the handler 20 and for example loaded into a dedicated classifying machine. At this dedicated classifying machine, the DUTs are classified into categories in accordance with the results of the tests by the tester body 5 of the electronic device test apparatus 1.

As explained above, in the present embodiment, the plate stack 63 of the pushing unit 61 has a rigidity which is lower relative to the rigidity of the spacing frame 14 of the HIFIX 11, so the plate stack 63 deforms so as to match the flexing of the spacing frame 14 and occurrence of poor contact between the DUTs and the sockets 12 can be suppressed.

### Second Embodiment

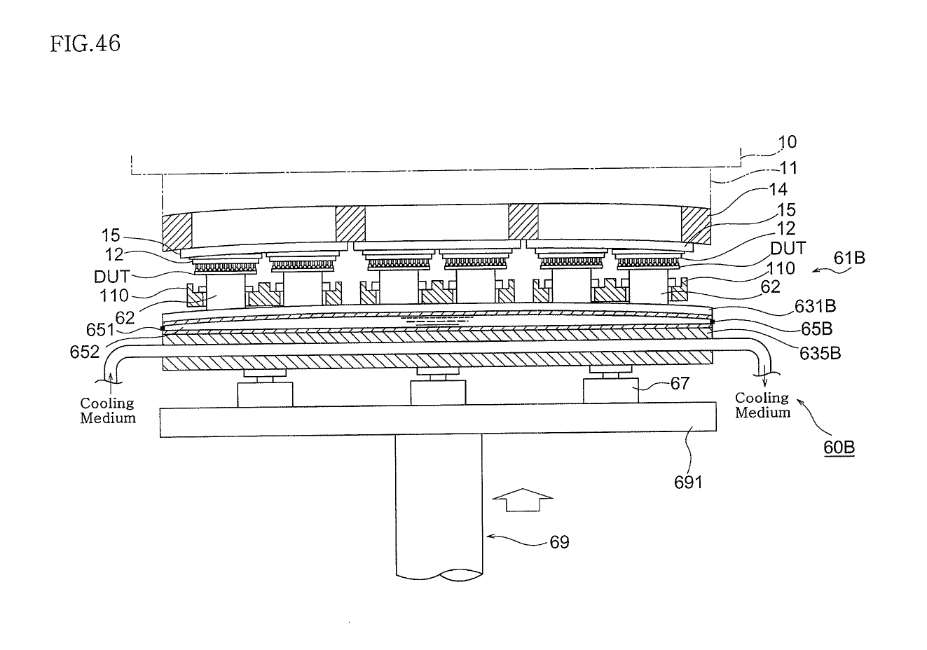

FIG. 45 is a cross-sectional view showing a pushing apparatus in a second embodiment of the present invention, while FIG. 46 is a view showing the action of the pushing apparatus shown in FIG. 45.

In the present embodiment, the configuration of the pushing unit 61B of the pushing apparatus 60B differs from that of the first embodiment, but the rest of the configuration is similar to that of the first embodiment. Below, only the points of difference of the electronic device test apparatus of the second embodiment from the first embodiment will be explained. Parts configured similarly to the first embodiment will be assigned the same reference signs and explanations will be omitted.

In the pushing unit 61B in the present embodiment, first, the base plate 631B is set to a rigidity which is lower relative to the rigidity of the spacing frame 14 of the HIFIX 11. Specifically, the base plate 631B is made thinner, the base plate 631B is formed with cutaway parts, or the base plate 631B is configured by a low strength material so as to lower the rigidity of the base plate 631B.

On the other hand, the rigidity of the temperature regulating plate 635B is set higher relative to the rigidity of the spacing frame 14. Specifically, the temperature regulating plate 635B is made thicker or the temperature regulating plate 635B is made from a high strength material so as to increase the rigidity of the temperature regulating plate 635.

Further, in the present embodiment, as shown in FIG. 45, a heat conduction member 65B is interposed between the base plate 631B and the temperature regulating plate 635B. This heat conduction member 65B, for example, comprises a bellows 561 at the inside space of which a liquid 652 which is excellent in heat conductivity (for example, Fluorinert® made by 3M) is filled and can deform to follow the base plate 631B.

If using this pushing unit 61B to push the DUTs to the sockets 12, as shown in FIG. 46, along with the pushing action of the pushing apparatus 60B, the spacing frame 14 of the HIFIX 11 flexes. At this time, in the present embodiment, since the base plate 631B is set to a rigidity which is lower relative to the rigidity of the spacing frame 14, the base plate 6318 deforms so as to match the flexing of the spacing frame 14. For this reason, occurrence of poor contact between the DUTs and sockets 12 can be suppressed.

On the other hand, in the present embodiment, the temperature regulating plate 635B is set to a rigidity which is higher relative to the rigidity of the spacing frame 14, so even if the spacing frame 14 flexes, the temperature regulating plate 635B does not deform at all. However, the heat conduction member 65B which deforms in accordance with the base plate 631B is interposed between this temperature regulating plate 635B and base plate 631B, so a path for heat conduction is secured from the temperature regulating plate 6358 to the base plate 631B.

### Third Embodiment

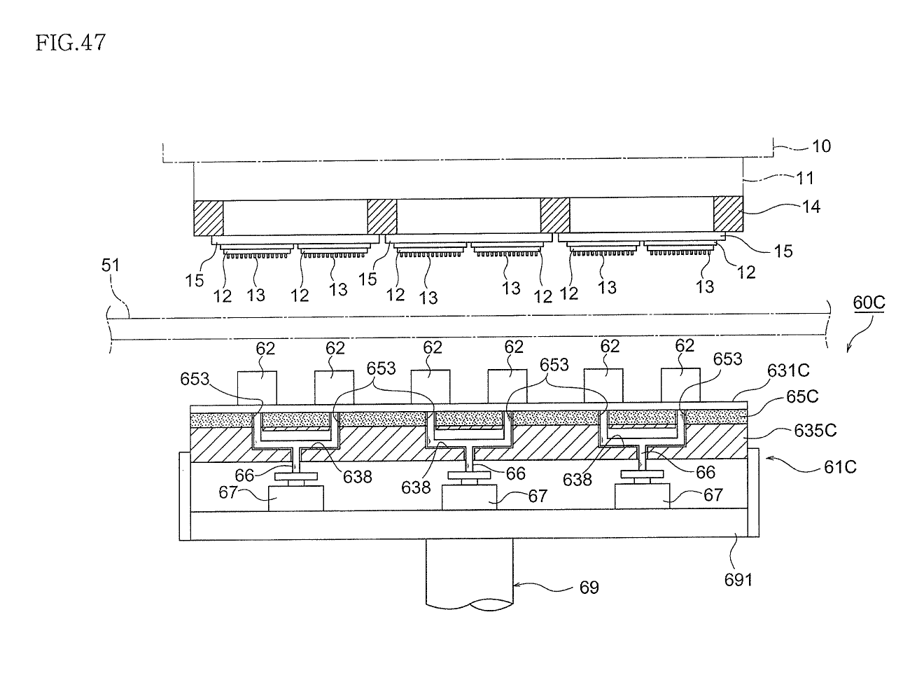

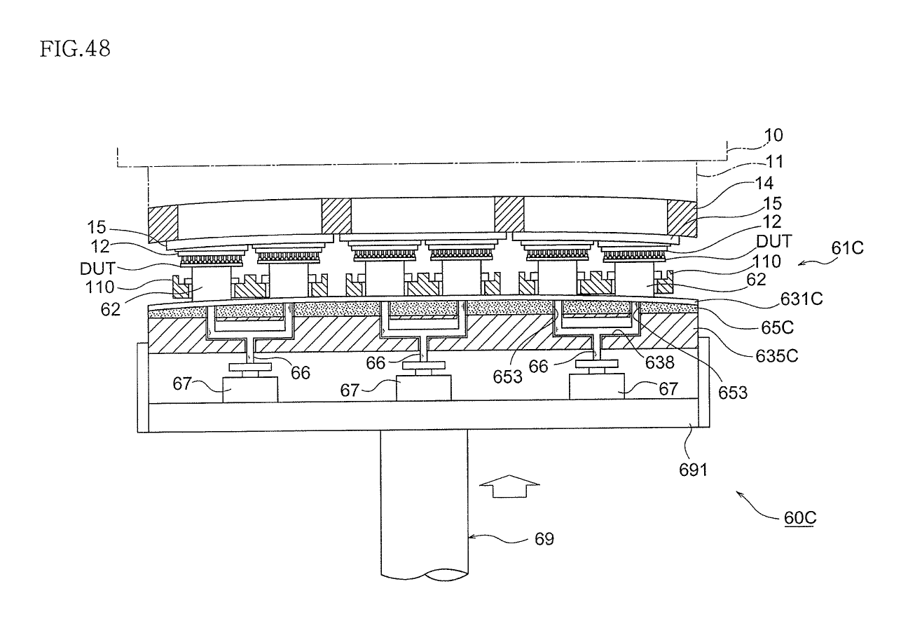

FIG. 47 is a cross-sectional view showing a pushing apparatus in a third embodiment of the present invention, while FIG. 48 is a view showing the action of the pushing apparatus shown in FIG. 47.

In the present embodiment, the configuration of the pushing apparatus 60C differs from that of the first embodiment, but the rest of the configuration is similar to that of the first embodiment. Below, only the points of difference of the electronic device test apparatus of the third embodiment from the first embodiment will be explained. Parts configured similarly to the first embodiment will be assigned the same reference signs and explanations will be omitted.

In the pushing unit 61C in the present embodiment, the base plate 631C is set to a rigidity which is lower relative to the rigidity of the spacing frame 14 of the HIFIX 11. On the other hand, the temperature regulating plate 635C is set to a rigidity which is higher relative to the rigidity of the spacing frame 14. Note that, while not particularly shown in FIG. 47, in the same way as the first embodiment, the temperature regulating plate 635C in the present embodiment is also formed with a channel through which a cooling medium can be run.

Further, in the present embodiment, as shown in FIG. 47, a heat conduction member 65C is interposed between the base plate 631C and the temperature regulating plate 635C. The heat conduction member 65C in the present embodiment is, for example, a sheet-shaped member which comprises a rubber sheet etc. containing metal particles or carbon particles or other conductive particles and can deform to follow the base plate 631C. Note that, instead of the heat conduction member 65C which comprises the sheet-shaped member, the heat conduction member 65B which was explained in the second embodiment may also be interposed between the base plate 631C and the temperature regulating plate 635C.

Further, in the present embodiment, shafts 66 are interposed between the base plate 631C and the bellofram cylinders 67. Each of the shafts 66 has a shape branched at the intermediate part so as to correspond to the pushers 62 on the base plate 631C. The shafts 66 are inserted into through holes 638 and 653 which are formed in the temperature regulating plate 635C and heat conduction member 65C so as to be able to move up and down. Their back ends abut against the bellofram cylinders 67, while their front ends abut against the base plate 631C at positions corresponding to the pushers 62.

If using this pushing unit 61C to push the DUTs to the sockets 12, as shown in FIG. 48, along with the pushing action of the pushing unit 61C, the spacing frame 14 of the HIFIX 11 flexes. At this time, in the present embodiment, since the base plate 631C is set to a rigidity which is lower relative to the rigidity of the spacing frame 14, the base plate 631C deforms so as to match the flexing of the spacing frame 14. For this reason, occurrence of poor contact between the DUTs and sockets 12 can be suppressed.

On the other hand, in the present embodiment, the temperature regulating plate 635C is set to a rigidity which is higher relative to the rigidity of the spacing frame 14, so even if the spacing frame 14 flexes, the temperature regulating plate 635C does not deform. However, the heat conduction member 65C which deforms in accordance with the base plate 631C is interposed between this temperature regulating plate 635C and base plate 631C, so a path for heat conduction is secured from the temperature regulating plate 635C to the base plate 631C.

### Fourth Embodiment

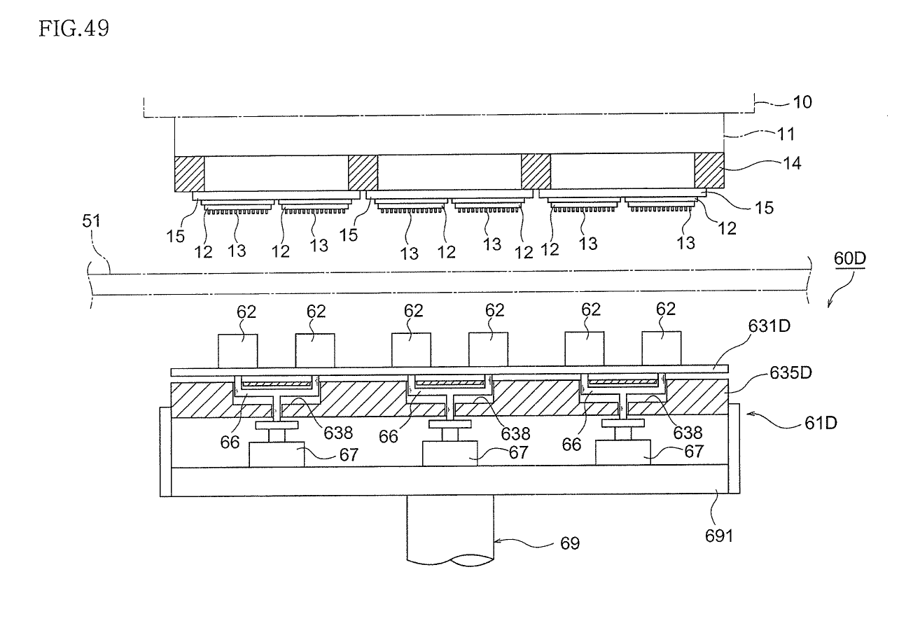

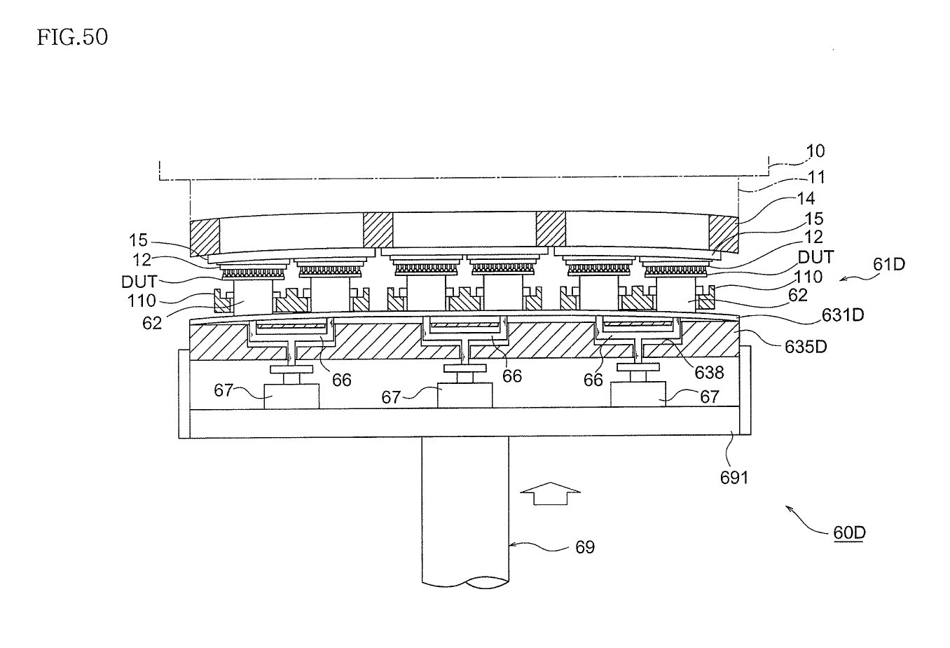

FIG. 49 is a cross-sectional view showing a pushing apparatus in a fourth embodiment of the present invention, while FIG. 50 is a view showing the action of the pushing apparatus shown in FIG. 49.

In the present embodiment, the configuration of the pushing unit 61D of the pushing apparatus 60D differs from that of the first embodiment, but the rest of the configuration is similar to that of the first embodiment. Below, only the points of difference of the electronic device test apparatus of the fourth embodiment from the first embodiment will be explained. Parts configured similarly to the first embodiment will be assigned the same reference signs and explanations will be omitted.

In the pushing unit 61D in the present embodiment, the base plate 631D is set to a rigidity which is lower relative to the rigidity of the spacing frame 14 of the HIFIX 11. On the other hand, the temperature regulating plate 635D is set to a rigidity which is higher relative to the rigidity of the spacing frame 14. Note that, while not particularly shown in FIG. 49, in the same way as the first embodiment, the temperature regulating plate 635D in the present embodiment is also formed with a channel through which a cooling medium can be run.

Further, in the present embodiment, shafts 66 are interposed between the base plate 631D and the bellofram cylinders 67. Each of the shaft 66, in the same way as in the third embodiment, has a shape branched at the intermediate part so as to correspond to the pushers 62 on the base plate 631D. The shafts 66 are inserted into through holes 638 which are formed in the temperature regulating plate 635D so as to be able to move up and down. Their back ends abut against the bellofram cylinders 67, while their front ends abut against the base plate 631D at positions corresponding to the pushers 62.

If using this pushing unit 60D to push the DUTs to the sockets 12, as shown in FIG. 50, along with the pushing action of the pushing unit 60D, the spacing frame 14 of the HIFIX 11 flexes. At this time, in the present embodiment, since the base plate 631D is set to a rigidity which is lower relative to the rigidity of the spacing frame 14, the base plate 631D deforms so as to match the flexing of the spacing frame 14. For this reason, occurrence of poor contact between the DUTs and sockets 12 can be suppressed.

Note that, in the present embodiment, a path for heat conduction is secured from the temperature regulating plate 635D to the base plate 631D by the shafts 66.

### Fifth Embodiment

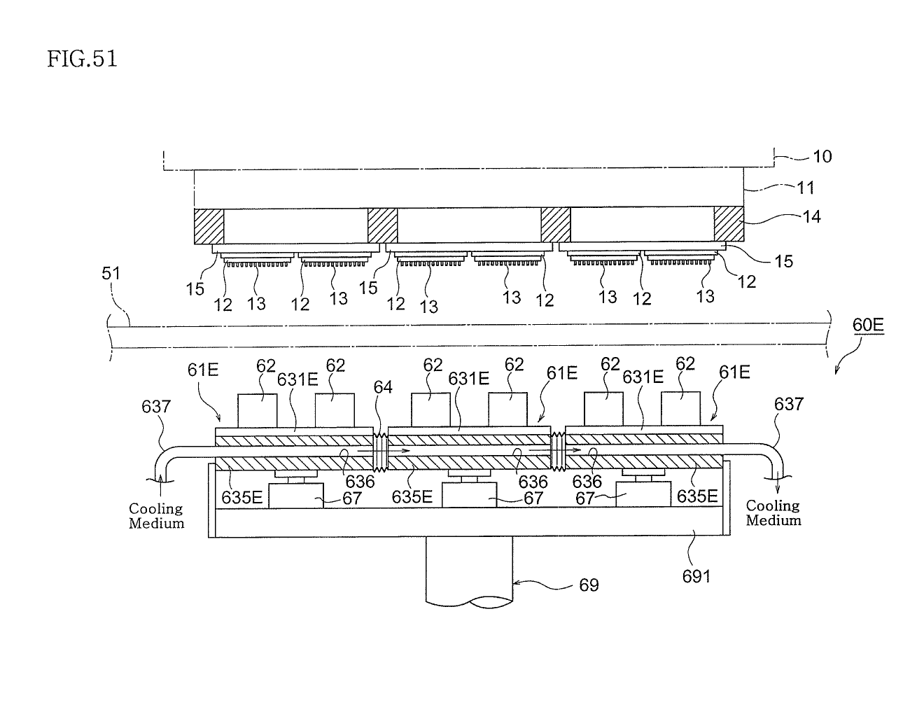

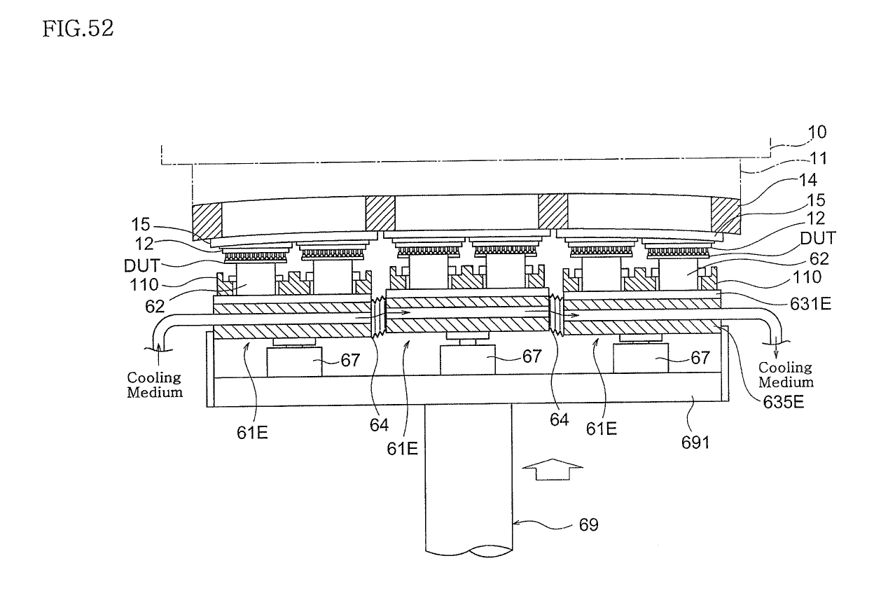

FIG. 51 is a cross-sectional view showing a pushing apparatus in a fifth embodiment of the present invention, while FIG. 52 is a view showing the action of the pushing apparatus shown in FIG. 51.

In the present embodiment, the configuration of the pushing apparatus 60E differs from that of the first embodiment, but the rest of the configuration is similar to that of the first embodiment. Below, only the points of difference of the electronic device test apparatus of the fifth embodiment from the first embodiment will be explained. Parts configured similarly to the first embodiment will be assigned the same reference signs and explanations will be omitted.

As shown in FIG. 51, the pushing apparatus 60E in the present embodiment comprises a plurality of pushing units 61E. Each of these pushing units 61E has: a predetermined number of pushers 62; a base plate 631E on which the pushers 62 is provided to stick out; a temperature regulating plate 635E which is superposed on the base plate 631E; and a bellofram cylinder 67 which applies a predetermined pressure to the base plate 631E through the temperature regulating plate 635E. Each of the pushing units 61E is designed to be able to move up and down independent of the others.

Further, in the present embodiment, the temperature regulating plate 635E of each pushing unit 61E is formed with a channel 636 similar to the first embodiment, a bellows 64 (channel connecting means) is interposed between each two pushing units 61E, and the channels 636 of the pushing units 61E are connected to each other by the bellows 64.

If using this pushing apparatus 60E to push the DUTs to the sockets 12, as shown in FIG. 52, along with the pushing action of the pushing apparatus 60E, the spacing frame 14 of the HIFIX 11 flexes. At this time, in the present embodiment, a plurality of devided pushing units 61E are formed in units of predetermined numbers of pushers 62. Further, the plurality of pushing units 61E are designed to be able to move up and down independently of each other. For this reason, along with flexing of the spacing frame 14, the pushing units 61E change in heights. Therefore, flexing of the spacing frame 14 can be absorbed, and occurrence of poor contact between the DUTs and sockets 12 can be suppressed.

Note that, in each pushing unit 61E, a heat conduction member 65B or 65C explained in the second embodiment or third embodiment may be interposed between the base plate 631E and the temperature regulating plate 635E.

### Sixth Embodiment

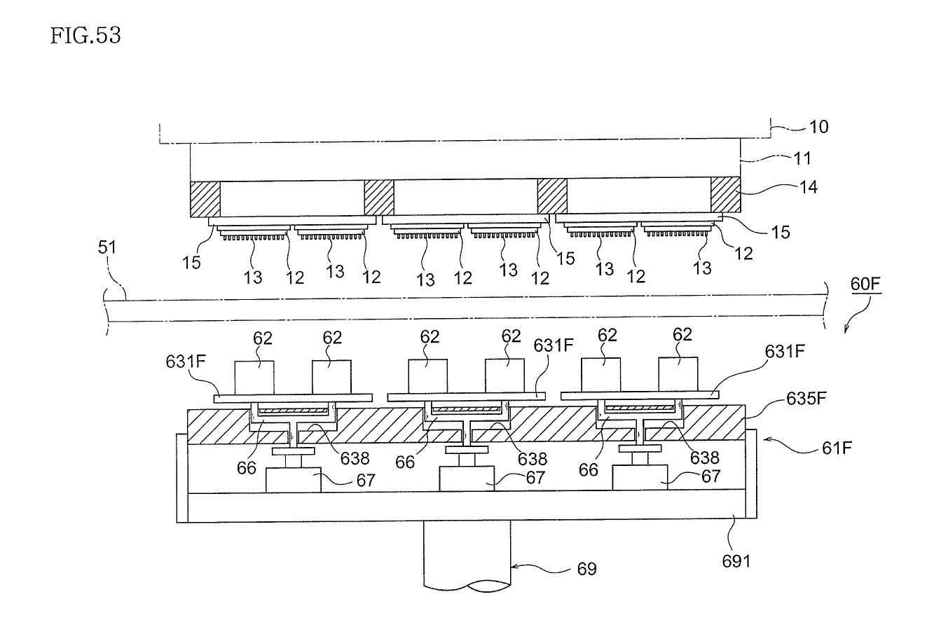

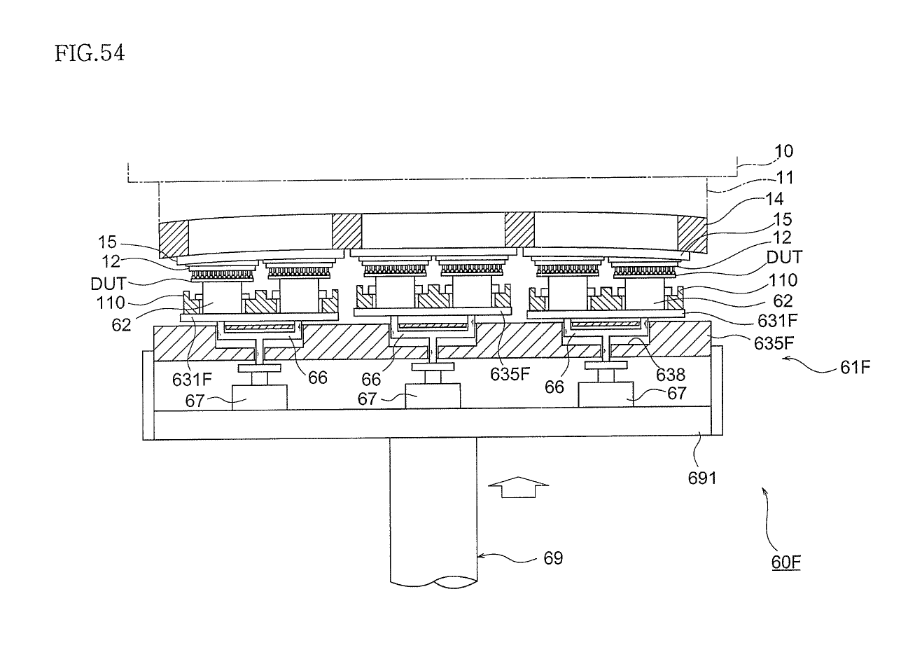

FIG. 53 is a cross-sectional view showing a pushing apparatus in a sixth embodiment of the present invention, while FIG. 54 is a view showing the action of the pushing apparatus shown in FIG. 53.

In the present embodiment, the configuration of the pushing unit 61F of the pushing apparatus 60F differs from that of the first embodiment, but the rest of the configuration is similar to that of the first embodiment. Below, only the points of difference of the electronic device test apparatus of the sixth embodiment from the first embodiment will be explained. Parts configured similarly to the first embodiment will be assigned the same reference signs and explanations will be omitted.

As shown in FIG. 53, in the pushing unit 61F in the present embodiment, divided base plates 631F are formed in units of predetermined numbers of pushers 62.

Further, in the present embodiment, shafts 66 are interposed between the base plates 631F and bellofram cylinders 67. Each of the shafts 66, in the same way as in the third and fourth embodiments, has a shape branched at the intermediate part so as to correspond to the pushers 62 on the base plates 631F. The shafts 66 are inserted into through holes 638 which are formed in the temperature regulating plate 635F so as to be able to move up and down. Their back ends abut against the bellofram cylinders 67, while their front ends abut against the base plates 631F at positions corresponding to the pushers 62. Note that, while not particularly shown in FIG. 53, in the same way as the first embodiment, the temperature regulating plate 635F in the present embodiment is also formed with a channel through which a cooling medium can be run.

If using this pushing unit 61F to push the DUTs to the sockets 12, as shown in FIG. 54, along with the pushing action of the pushing unit 61F, the spacing frame 14 of the HIFIX 11 flexes. At this time, in the present embodiment, since the divided base plates 631F are designed to be able to move up and down independently of each other, the base plates 631F change in heights in accordance with the flexing of the spacing frame 14, so flexing of the spacing frame 14 can be absorbed. For this reason, occurrence of poor contact between the DUTs and sockets 12 can be suppressed.

Note that, a heat conduction member 65B or 65C explained in the second embodiment or third embodiment may be interposed between each base plate 631F and the temperature regulating plate 635F.

### Seventh Embodiment

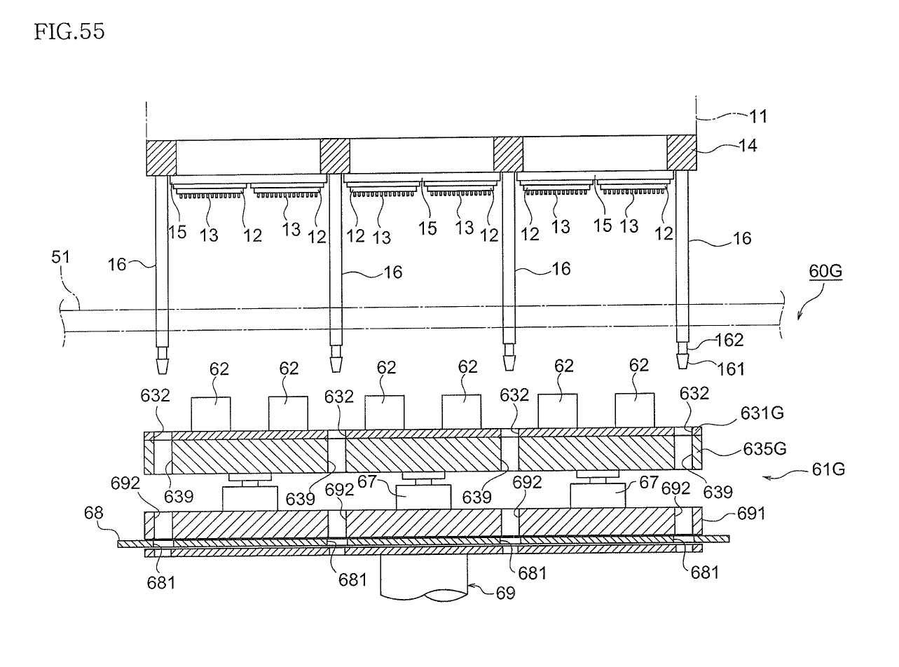

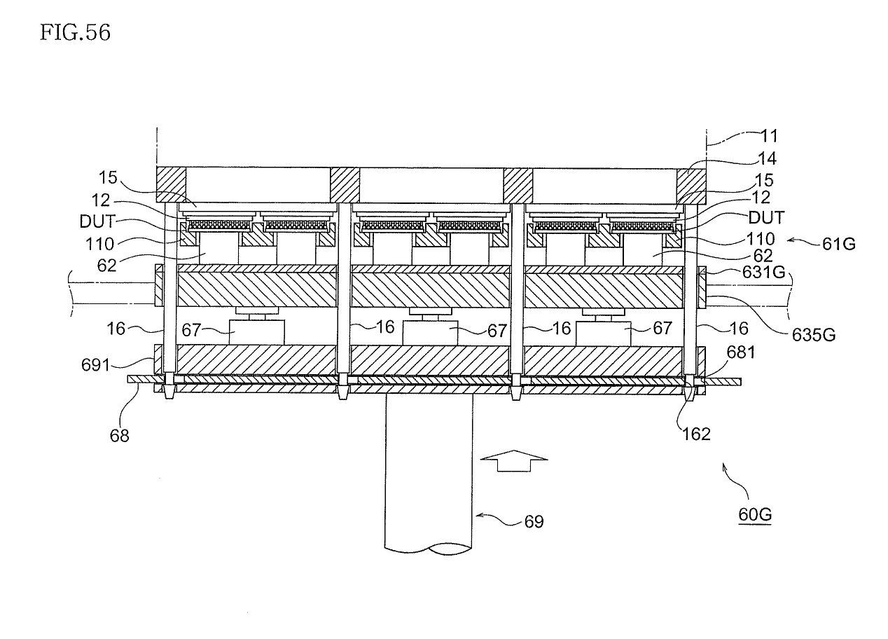

FIG. 55 is a cross-sectional view showing a pushing apparatus in a seventh embodiment of the present invention, while FIG. 56 is a view showing the action of the pushing apparatus shown in FIG. 55.

In the present embodiment, the HIFIX 11 is provided with engagement shafts 16 and the configuration of the pushing apparatus 60G differs from that of the first embodiment, but the rest of the configuration is similar to that of the first embodiment. Below, only the points of difference of the electronic device test apparatus of the seventh embodiment from the first embodiment will be explained. Parts configured similarly to the first embodiment will be assigned the same reference signs and explanations will be omitted.

As shown in FIG. 55, in the HIFIX 11 in the present embodiment, engagement shafts 16 are upright provided at the spacing frame 14. The engagement shafts 16 stick out toward the pushing apparatus 60G and have tapered front ends 161. Engagement grooves 162 are formed near the front ends 161.

On the other hand, the base plate 631G, temperature regulating plate 635G, and elevating plate 691 of the pushing apparatus 60G are formed with through holes 632, 639, and 692 at positions corresponding to the engagement shaft 16. Note that, while not particularly shown in FIG. 55, in the same way as the first embodiment, the temperature regulating plate 635G in the present embodiment is also formed with a channel through which a cooling medium can be run.

Further, a lock plate 68 (connecting means) is inserted at the Z-axis actuator 69 in a slidable manner. This lock plate 68 is formed with engagement holes 681 at positions corresponding to the engagement shafts 16.

When this pushing apparatus 60G is used to push DUTs to the sockets 12, as shown in FIG. 56, the engagement shafts 16 of the HIFIX 11 are inserted through the through holes 632, 639, and 692 of the base plate 631G, temperature regulating plate 635G, and elevating plate 691. By sliding the lock plate 68, the lock plate 68 is engaged with the engagement grooves 162 of the engagement shafts 16. Due to this, flexing of the spacing frame 14 of the HIFIX 11 is suppressed, so occurrence of poor contact between the DUTs and sockets 12 can be suppressed.

Note that the embodiments explained above were described for facilitating understanding of the present invention and were not described for limiting the present invention. Therefore, the elements disclosed in the above embodiments include all design modifications and equivalents falling under the technical scope of the present invention.

### REFERENCE SIGNS LIST

10 . . . test head
11 . . . HIFIX
12 . . . socket
14 . . . spacing frame
16 . . . engagement shaft
20 . . . handler
60, 60B to 60G . . . pushing apparatus
61, 61B to 61G . . . pushing unit
62 . . . pushers
63 . . . plate stack
631, 631B to 631G . . . base plate
635, 635B to 635G . . . temperature regulating plate
64 . . . bellows
65B, 65C . . . heat conduction member
66 . . . shaft
67 . . . bellofram cylinder
68 . . . lock plate
69 . . . Z-direction actuator
691 . . . elevating plate
110 . . . contact plate

1. An electronic device pushing apparatus which pushes devices under test to sockets on an interface device which is mounted on a test head,
the electronic device pushing apparatus comprising a pushing unit which has: a plurality of pushers which contact the devices under test; and a base plate on which the plurality of pushers are provided, wherein and
the base plate has a rigidity which is lower relative to a rigidity of a holding member which holds the sockets in the interface device.

2. The electronic device pushing apparatus as set forth in claim 1, wherein
the pushing unit has a temperature regulating plate which regulates a temperature of the devices under test, and
the temperature regulating plate is stacked over the base plate.

3. The electronic device pushing apparatus as set forth in claim 2, wherein
the temperature regulating plate has a channel through which at least one of a cooling medium or heating medium flows.

4. The electronic device pushing apparatus as set forth in claim 1, wherein
the holding member is a spacing frame which holds socket boards on which the sockets are mounted in the interface device.

5. The electronic device pushing apparatus as set forth in claim 2, wherein
a plate stack which comprises the base plate and the temperature regulating plate stacked together has a rigidity which is lower relative to the rigidity of the holding member.

6. The electronic device pushing apparatus as set forth in claim 5, comprising
a moving device configured to move the pushing unit toward the sockets, wherein
the pushing unit has a cylinder which applies a predetermined pressure to the base plate.

7. The electronic device pushing apparatus as set forth in claim 2, wherein
the pushing unit has:
a cylinder which applies a predetermined pressure to the base plate; and
a shaft which is arranged between the cylinder and the base plate and which passes through the temperature regulating plate.

8. The electronic device pushing apparatus as set forth in claim 7, comprising
a moving device configured to move the pushing unit toward the sockets.

9. The electronic device pushing apparatus as set forth in claim 2, wherein
the pushing unit comprises a heat conduction member which is stacked between the base plate and the temperature regulating plate and which thermally connects the base plate and the temperature regulating plate, and
the heat conduction member is able to deform together with the base plate.

10. The electronic device pushing apparatus as set forth in claim 9, wherein
the heat conduction member is bag member in which a fluid is filled.

11. The electronic device pushing apparatus as set forth in claim 9, wherein
the heat conduction member is a sheet-shaped member which can elastically deform.

12. The electronic device pushing apparatus as set forth in claim 9, comprising
a moving device configured to move the pushing unit toward the sockets, wherein
the pushing unit has:
a cylinder which applies a predetermined pressure to the base plate; and
a shaft which is arranged between the cylinder and the base plate and which passes through the temperature regulating plate and the heat conduction member.

13. An electronic device pushing apparatus which pushes devices under test to sockets on an interface device which is mounted on a test head,
the electronic device pushing apparatus comprising
a plurality of pushing units which push the devices under test, wherein
each of the pushing units has:
a plurality of pushers which contact the devices under test; and
a base plate on which the plurality of pushers are provided, and
the plurality of pushing units can move independently of each other.

14. The electronic device pushing apparatus as set forth in claim 13, wherein
a holding member which holds the sockets in the interface device is a spacing frame which holds socket boards on which the sockets are mounted.

15. The electronic device pushing apparatus as set forth in claim 13, comprising
a moving device configured to simultaneously move the plurality of pushing units toward the sockets, wherein
each of the pushing units has a cylinder which applies a certain pressure to the base plate.

16. The electronic device pushing apparatus as set forth in claim 13, wherein
each of the pushing units has a temperature regulating plate which is stacked on the base plate and which regulates the temperature of the devices under test.

17. The electronic device pushing apparatus as set forth in claim 16, wherein
the temperature regulating plate has a channel through which at least one of a cooling medium or heating medium flows.

18. The electronic device pushing apparatus as set forth in claim 17, comprising
a channel connecting device configured to connect channels of the temperature regulating plates, wherein
the channel connecting device is interposed between the plurality of pushing units.

19. The electronic device pushing apparatus as set forth in claim 16, wherein
each of the pushing units comprises a heat conduction member which is stacked between the base plate and the temperature regulating plates and which thermally connects the base plate and the temperature regulating plates.

20. The electronic device pushing apparatus as set forth in claim 19, wherein
the heat conduction member is bag member in which a fluid is filled.

21. The electronic device pushing apparatus as set forth in claim 19, wherein
the heat conduction member is a sheet-shaped member which can elastically deform.

22. An electronic device pushing apparatus which pushes devices under test to sockets on an interface device which is mounted on a test head,
the electronic device pushing apparatus comprising:
a pushing unit which pushes the devices under test; and
a moving device configured to move the pushing unit toward the sockets, wherein
the pushing unit has:
a plurality of base plates on which pluralities of pushers which contact the device under test are respectively provided;
a plurality of cylinders which apply predetermined pressure to the base plates; and
a plurality of shafts which are arranged between the base plates and the cylinders.

23. The electronic device pushing apparatus as set forth in claim 22, wherein
the pushing unit has a temperature regulating plate which regulates the temperature of the devices under test, and
the shaft passes through the temperature regulating plate.

24. The electronic device pushing apparatus as set forth in claim 23, wherein
the temperature regulating plate has a channel through which at least one of a cooling medium or heating medium flows.

25. The electronic device pushing apparatus as set forth in claim 23, wherein
the pushing unit comprises a heat conduction member which is stacked between the base plate and the temperature regulating plate and which thermally connects the base plate and the temperature regulating plate, and
the shaft passes through the heat conduction member.

26. The electronic device pushing apparatus as set forth in claim 25, wherein
the heat conduction member is a bag member in which a fluid is filled.

27. The electronic device pushing apparatus as set forth in claim 25, wherein
the heat conduction member is a sheet-shaped member which can elastically deform.

28. An electronic device pushing apparatus which pushes devices under test to sockets on an interface device which is mounted on a test head,
the electronic device pushing apparatus comprising:
a base plate on which a plurality of pushers which contact the devices under test are provided; and
a coupling device which couples a holding member which holds the sockets in the interface device to the base plate.

29. The electronic device pushing apparatus as set forth in claim 28, comprising
a temperature regulating plate which regulates the temperature of the devices under test, wherein
the temperature regulating plate is stacked on the base plate.

30. The electronic device pushing apparatus as set forth in claim 29, wherein
the temperature regulating plate has a channel through which at least one of a cooling medium or heating medium flows.

31. The electronic device pushing apparatus as set forth in claim 28, wherein
the holding member is a spacing frame which holds socket boards on which the sockets are mounted in the test head.

32. The electronic device pushing apparatus as set forth in claim 28, comprising
a moving device configure to move the pushing unit toward the sockets, wherein
the pushing unit has a cylinder which applies a predetermined pressure to the base plate.

33. An electronic device test apparatus which tests devices under test,
a test head on which an interface device which has sockets which electrically contact the devices under test is mounted; and
an electronic device pushing apparatus as set forth in claim 1 which pushes the devices under test to the sockets.

34. An interface device which has sockets which electrically contact devices under test, which is mounted on a test head, and which electrically relays signals between the devices under test and the test head,
the interface device comprising
a holding member which holds the sockets, and
the holding member has a rigidity which is higher relative to a rigidity of a base plate on which a plurality of pushers which push the devices under test are provided.

35. The interface device as set forth in claim 34, wherein
the holding member is a spacing frame which holds socket boards on which the sockets are mounted.

36. An electronic device test apparatus which tests devices under test, comprising:
a test head on which an interface device which has sockets which electrically contact the devices under test is mounted; and
an electronic device pushing apparatus as set forth in claim 13 which pushes the devices under test to the sockets.

37. An electronic device test apparatus which tests devices under test, comprising:
a test head on which an interface device which has sockets which electrically contact the devices under test is mounted; and
an electronic device pushing apparatus as set forth in claim 22 which pushes the devices under test to the sockets.

38. An electronic device test apparatus which tests devices under test, comprising:
a test head on which an interface device which has sockets which electrically contact the devices under test is mounted; and
an electronic device pushing apparatus as set forth in claim 28 which pushes the devices under test to the sockets.
